(19) United States
(12) Patent Application Publication
(10) Pub. No.: US 2026/0047115 A1
(43) Pub. Date: Feb. 12, 2026

(54) SEMICONDUCTOR DEVICE

(71) Applicant: ROHM CO., LTD., Kyoto (JP)

(72) Inventor: Naoya NOZU, Kyoto (JP)

(73) Assignee: ROHM CO., LTD., Kyoto (JP)

(21) Appl. No.: 19/284,511

(22) Filed: Jul. 29, 2025

(30) Foreign Application Priority Data
Aug. 6, 2024 (JP) 2024-129811

(51) Int. Cl. H10D 1/68; H10D 1/00

(52) U.S. Cl. CPC H10D 1/716; H10D 1/042

(57) ABSTRACT

A semiconductor device, including: a semiconductor substrate having a first substrate surface and a second substrate surface opposite to each other; a trench recessed from the first substrate surface toward the second substrate surface, and has a width when viewed from a thickness direction of the semiconductor substrate; an insulating layer disposed inside the trench; and an electrode part disposed inside the trench and surrounded by the insulating layer, the electrode part having conductivity. The trench includes: a first trench part having a first width in a width direction of the trench, and a second trench part formed at a position different from that of the first trench part in the thickness direction and having a second width that is greater than the first width in the width direction.

### CROSS REFERENCE TO RELATED APPLICATION

This application is based upon and claims the benefit of priority of the prior Japanese Patent Application No. 2024-129811, filed on Aug. 6, 2024, the entire contents of which are incorporated herein by reference.

### TECHNICAL FIELD

The present disclosure relates to a semiconductor device.

### BACKGROUND ART

Japanese Patent Application Laid-open Publication No. 2017-195321 discloses a chip capacitor that includes a substrate, a first conductive film formed on the substrate, a dielectric film disposed on the first conductive film and substrate, and a second conductive film disposed on the dielectric film.

### BRIEF DESCRIPTION OF THE DRAWINGS

FIG. 1 is a schematic plan view of an illustrative semiconductor device of Embodiment 1.

FIG. 2 is a schematic plan view showing an enlarged view of a part of FIG. 1.

FIG. 3 is a schematic cross-sectional view of the semiconductor device, taken along the F3-F3 line of FIG. 2.

FIG. 4 is a schematic cross-sectional view showing an enlarged view of FIG. 3.

FIG. 5 is a schematic cross-sectional view showing an illustrative manufacturing process of the semiconductor device of FIG. 1.

FIG. 6 is a schematic cross-sectional view showing a manufacturing process subsequent to FIG. 5.

FIG. 7 is a schematic cross-sectional view showing a manufacturing process subsequent to FIG. 6.

FIG. 8 is a schematic cross-sectional view showing a manufacturing process subsequent to FIG. 7.

FIG. 9 is a schematic cross-sectional view showing a manufacturing process subsequent to FIG. 8.

FIG. 10 is a schematic cross-sectional view showing a manufacturing process subsequent to FIG. 9.

FIG. 11 is a schematic cross-sectional view showing a manufacturing process subsequent to FIG. 10.

FIG. 12 is a schematic cross-sectional view showing a manufacturing process subsequent to FIG. 11.

FIG. 13 is a schematic cross-sectional view showing a manufacturing process subsequent to FIG. 12.

FIG. 14 is a schematic cross-sectional view showing a manufacturing process subsequent to FIG. 13.

FIG. 15 is a schematic cross-sectional view showing a manufacturing process subsequent to FIG. 14.

FIG. 16 is a schematic cross-sectional view showing a manufacturing process subsequent to FIG. 15.

FIG. 17 is a schematic cross-sectional view showing a manufacturing process subsequent to FIG. 16.

FIG. 18 is a schematic plan view showing a semiconductor device of a comparison example.

FIG. 19 is a schematic cross-sectional view of the semiconductor device of the comparison example of FIG. 18.

FIG. 20 is a schematic plan view showing a semiconductor device of a modification example.

FIG. 21 is a schematic plan view showing a semiconductor device of a modification example.

FIG. 22 is a schematic plan view showing a semiconductor device of a modification example.

FIG. 23 is a schematic plan view showing a semiconductor device of a modification example.

FIG. 24 is a schematic cross-sectional view of the semiconductor device of FIG. 23.

FIG. 25 is a schematic cross-sectional view showing a semiconductor device of a modification example.

FIG. 26 is a schematic cross-sectional view showing a semiconductor device of a modification example.

FIG. 27 is a schematic cross-sectional view showing a semiconductor device of a modification example.

FIG. 28 is a schematic cross-sectional view showing a semiconductor device of a modification example.

### DETAILED DESCRIPTION OF EMBODIMENTS

Below, some embodiments of the present disclosure will be explained with reference to the drawings. For ease of explanation and clarification, components illustrated in the drawings are not necessarily drawn to the same scale. Also, for ease of understanding, hatching lines may be omitted in the cross-sectional views. The appended figures are merely illustrating embodiments of the present disclosure, and shall not be interpreted as limiting the present disclosure. In the present disclosure, such terms as “first” “second” and “third” are used to simply distinguish respective objects from each other, and do not rank those objects against one another.

The detailed description below includes devices, systems, and methods to realize the illustrative embodiments of the present disclosure. This detailed description is provided for explanation, and is not intended to limit embodiments of the present disclosure or application or use of such embodiments.

### EMBODIMENTS

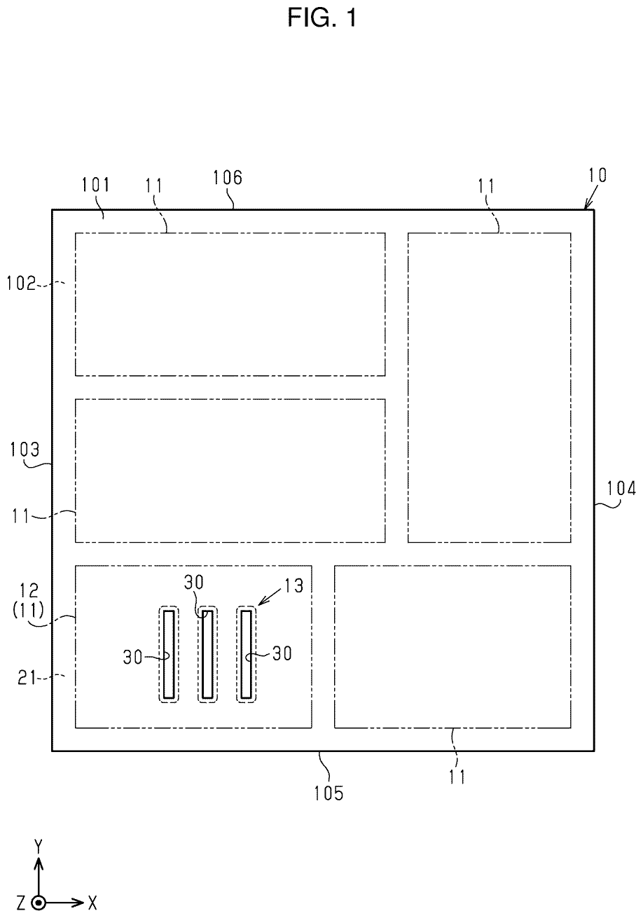

With reference to FIGS. 1 to 4, a semiconductor device 10 of an embodiment will be explained.

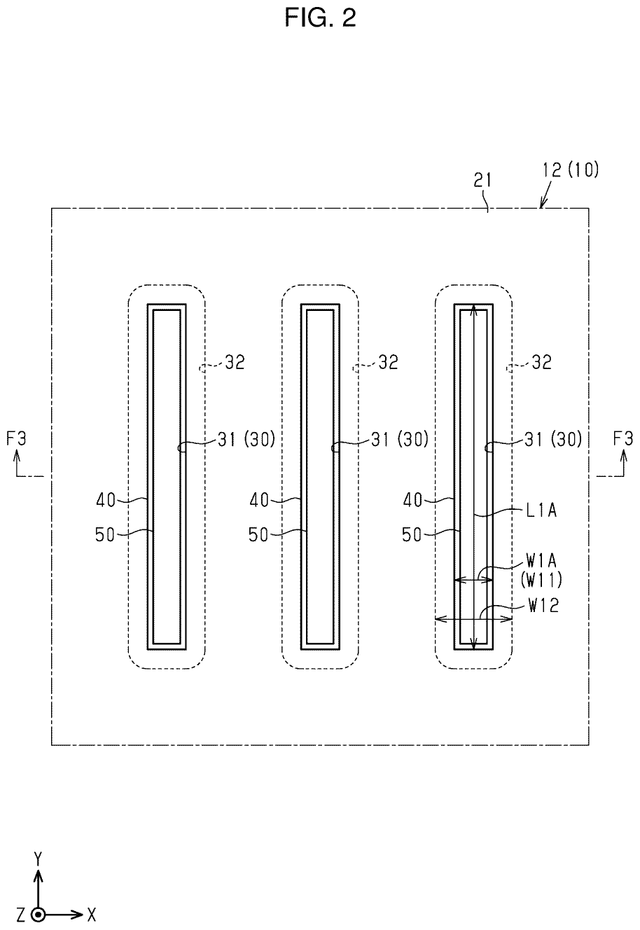

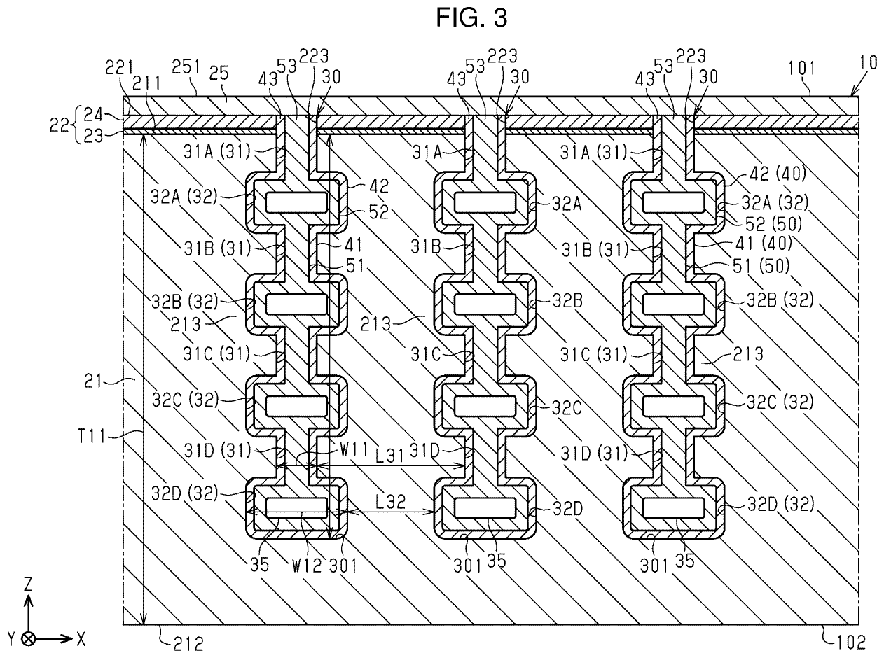

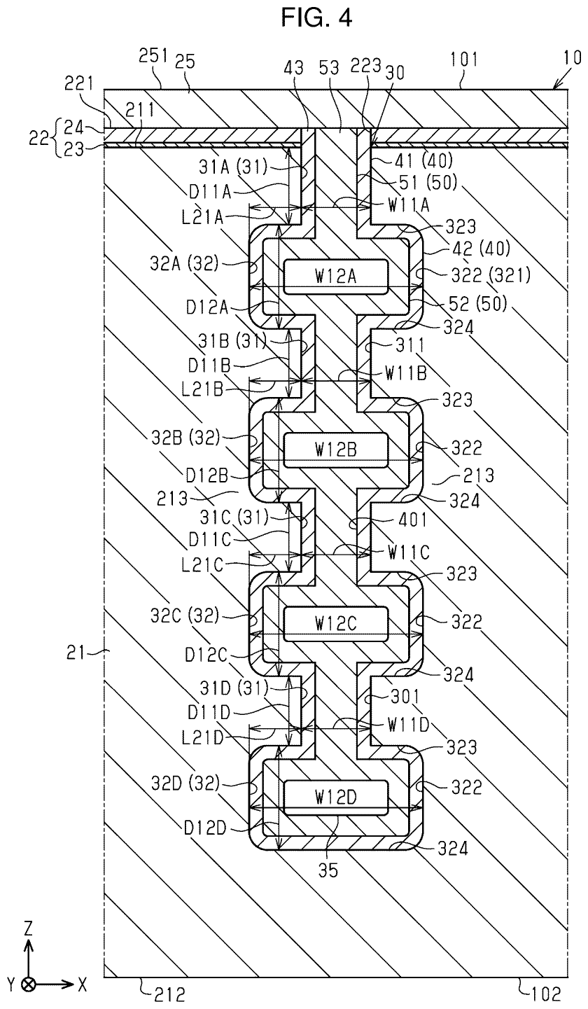

FIG. 1 is a schematic plan view of the semiconductor device 10. FIG. 2 is a schematic plan view showing an enlarged view of a part of FIG. 1. FIG. 3 is a schematic cross-sectional view of the semiconductor device 10, taken along the F3-F3 line of FIG. 2. FIG. 4 is a schematic cross-sectional view showing an enlarged view of FIG. 3. The term “in a plan view” used in the present disclosure means to see the semiconductor device 10 from the z-axis direction, which is one of the XYZ axes illustrated in FIG. 1.

As illustrated in FIG. 1, the semiconductor device 10 has a rectangular panel shape with the z-axis direction being the thickness direction. The semiconductor device 10 includes a device front surface 101, and a device rear surface 102 on the opposite side to the device front surface 101 in the z-axis direction. The semiconductor device 10 includes a plurality of device side surfaces 103, 104, 105, 106 that connect the device front surface 101 to the device rear surface 102. The device side surfaces 103 to 106 face one of the x-axis direction and the y-axis direction that are orthogonal to the z-axis direction and to each other. In one example, the device side surfaces 103 and 104 extend along the YZ plane, constituting respective end surfaces of the x-axis direction. The device side surfaces 105 and 106 extend along the XZ plane, constituting respective end surfaces of the y-axis direction.

In one example, the semiconductor device 10 includes a chip-shaped integrated circuit (IC) device. The semiconductor device 10 may be referred to as an SSI (Small Scale IC), MSI (Medium Scale IC), LSI (Large Scale IC), VLSI (Very Large Scale IC), ULSI (Ultra Large Scale IC) and the like, based on the number of circuit elements integrated therein.

In one example, the semiconductor device 10 includes a plurality of device regions 11. Respective adjacent device regions 11 are separated from each other in the x-axis direction or y-axis direction. The device regions 11 are separated from the device side surfaces 103 to 106. The number, arrangement, and shape of the device regions 11 included in the semiconductor device 10 may be modified as appropriate. The semiconductor device 10 may include at least one device region 11.

The device regions 11 may include function devices of the semiconductor device 10. The function devices include circuit elements such as transistors, capacitors, diodes, resistors, and the like. In one example, a device region 12 includes a capacitor 13.

The semiconductor device 10 may include a plurality of electrode pads exposed on the device front surface 101. The plurality of electrode pads are used for power supply and signal input/output to the function devices of the semiconductor device 10.

### (Overview of Capacitor Configuration)

The capacitor 13 is constituted of a semiconductor substrate 21, at least one trench 30 formed in the semiconductor substrate 21, and an insulating layer 40 and electrode part 50 disposed in the trench 30. In FIGS. 1 and 2, to illustrate the capacitor 13 more clearly, the first trench part 31 of the trench 30, the insulating layer 40, and the electrode part 50 are indicated with the solid line, and the second trench part 32 is indicated with the dashed line.

In one example, the semiconductor device 10 includes three trenches 30. The three trenches 30 are arranged along the x-axis direction in a plan view. Each of the trenches 30 extends along the y-axis direction in a plan view.

### (Configuration of Semiconductor Device Related to Capacitor)

As illustrated in FIGS. 3 and 4, the semiconductor substrate 21 has a first substrate surface 211 and a second substrate surface 212 on the opposite side to the first substrate surface 211. The second substrate surface 212 of the semiconductor substrate 21 may constitute the device rear surface 102 of the semiconductor device 10. The semiconductor substrate 21 includes a plurality of substrate side surfaces respectively constituting a part of the device side surfaces 103 to 106. The substrate side surfaces connect the first substrate surface 211 and the second substrate surface 212 to each other.

The semiconductor substrate 21 has a thickness T11 in the z-axis direction. The thickness T11 of the semiconductor substrate 21 may be 100 μm or greater and less than or equal to 500 μm.

The semiconductor substrate 21 may be made of a material containing Si (silicon). In one example, the semiconductor substrate 21 may be a silicon substrate. The semiconductor substrate 21 may include an epitaxial layer. The semiconductor substrate 21 may include an impurity, or may not include an impurity. The impurity may be of the first conductive type. In one example, the semiconductor substrate 21 may be a silicon substrate including a first conductive type impurity. The first conductive type may be p-type, for example. The resistivity of the semiconductor substrate 21 may be set to 5 mΩ·cm or greater and less than or equal to 100 mΩ·cm by introducing p-type impurity.

The semiconductor substrate 21 may be made of a compound semiconductor. The compound semiconductor may be a III-V compound semiconductor, IV-IV compound semiconductor, and an alloy semiconductor using these semiconductors. The III-V compound semiconductor is a Ga semiconductors such as GaAs or GaN, for example. The IV-IV compound semiconductor is an Si semiconductors such as SiC and SiGe, for example.

The semiconductor device 10 may include a surface insulating layer 22. The surface insulating layer 22 may cover the first substrate surface 211 of the semiconductor substrate 21. In one example, the surface insulating layer 22 entirely covers the first substrate surface 211 of the semiconductor substrate 21. In one example, the surface insulating layer 22 includes a first insulating layer 23 and a second insulating layer 24. The first insulating layer 23 is made of a material that includes at least one of SiO₂ (silicon oxide), SiN (silicon nitride), SiON (silicon oxynitride), and Al₂O₃ (aluminum oxide). In one example, the first insulating layer 23 is made of SiN. The second insulating layer 24 is made of a material containing at least one of SiO₂, SiN, SiON, Al₂O₃. In one example, the second insulating layer 24 is made of SiO₂. The surface insulating layer 22 may have a single-layer structure. The insulating layer may be constituted of three or more insulating layers.

The semiconductor device 10 may include a conductive part 25. The conductive part 25 may include an insulating layer and a wiring layer. The insulating layer may be constituted of a plurality of insulating films. The plurality of insulating films may be referred to as an interlayer insulating films. The wiring layer may include a plurality of layer wiring lines, via conductors connecting the layer wiring lines, a pad electrode for external connection, and the like. The wiring layer connects the function devices of the device regions 11 illustrated in FIG. 1. The capacitor 13 is connected to the function devices through the wiring layer. A surface 251 of the conductive part 25 may constitute the device front surface 101 of the semiconductor device 10.

The semiconductor device 10 includes a trench 30 formed in the semiconductor substrate 21. The trench 30 is recessed from the first substrate surface 211 toward the second substrate surface 212 of the semiconductor substrate 21. The trench 30 has a width W1A in a plan view, or when viewed from the thickness direction of the semiconductor substrate 21. In one example, the trench 30 is disposed such that the width W1A corresponds to the length thereof in the x-axis direction. The widths W1A of the plurality of trenches 30 may be the same as each other. The trench 30 extends along the y-axis direction. The trench 30 has a length L1A in the y-axis direction. In one example, the length L1A of the trench 30 may be the length of a first trench part 31 in the y-axis direction. Alternatively, the length L1A of the trench 30 may be the length of a second trench part 32 in the y-axis direction. The lengths L1A of the plurality of trenches 30 may be the same as each other. The plurality of trenches 30 are formed by removing portions of the semiconductor substrate 21.

The trench 30 has an inner surface 301 located in the semiconductor substrate 21. The semiconductor device 10 includes an insulating layer 40 disposed on the inner surface 301 of the trench 30. The insulating layer 40 has an insulating property. In one example, the insulating layer 40 may be made of a material containing Si. In one example, the insulating layer 40 may be an oxide film such as SiO₂. The insulating layer 40 may be a SiN film. The insulating layer 40 may be an SiO₂/SiN laminated film, or SiO₂/SiN/SiO₂ laminated film. The insulating layer 40 may be an ON film or ONO film, or a laminated film of those. The insulating layer 40 may be an insulating film made of a high-dielectric material (High-k material).

The electrode part 50 is disposed inside the trench 30. The electrode part 50 is surrounded by the insulating layer 40. The electrode part 50 has conductivity. In one example, the electrode part 50 may be formed of polysilicon. The polysilicon may have impurity added thereto. The electrode part 50 may be constituted of a conductive layer of polysilicon without impurity added, and a conductive layer of polysilicon with impurity added. The impurity added to polysilicon may be p-type impurity or n-type impurity.

The electrode part 50 faces the inner surface 301 of the trench 30 with the insulating layer 40 interposed therebetween. That is, the electrode part 50 faces the semiconductor substrate 21 with the insulating layer 40 interposed therebetween. The capacitor 13 is constituted of the insulating layer 40 as well as the electrode part 50 and the semiconductor substrate 21 that face each other via the insulating layer 40.

### (Configuration of Trench)

The trench 30 includes a first trench part 31 and a second trench part 32. The second trench part 32 is disposed at a location differing from the first trench part 31 in a z-axis direction.

As illustrated in FIGS. 3 and 4, the trench 30 includes four first trench parts 31A, 31B, 31C and 31D, and four second trench parts 32A, 32B, 32C and 32D. The number of the first trench part 31 may be modified to any number that is one or greater. The number of the second trench part 32 may be modified to any number that is one or greater.

In the description below, when it is not necessary to distinguish the respective first trench parts 31A, 31B, 31C, and 31D from each other, they are simply referred to as the first trench part 31. Similarly, when it is not necessary to distinguish the respective second trench parts 32A, 32B, 32C, and 32D from each other, they are simply referred to as the second trench part 32.

As illustrated in FIG. 4, the first trench parts 31A to 31D and the second trench parts 32A to 32D are alternately arranged in the z-axis direction. In the z-axis direction, the first trench parts 31A to 31D and the second trench parts 32A to 32D are connected.

The first trench part 31A extends from the first substrate surface 211 toward the second substrate surface 212 of the semiconductor substrate 21. The second trench part 32A extends from the first trench part 31A toward the second substrate surface 212 of the semiconductor substrate 21. The first trench part 31B extends from the second trench part 32A toward the second substrate surface 212 of the semiconductor substrate 21. The second trench part 32B extends from the first trench part 31B toward the second substrate surface 212 of the semiconductor substrate 21. The first trench part 31C extends from the second trench part 32B toward the second substrate surface 212 of the semiconductor substrate 21. The second trench part 32C extends from the first trench part 31C toward the second substrate surface 212 of the semiconductor substrate 21. The first trench part 31D extends from the second trench part 32C toward the second substrate surface 212 of the semiconductor substrate 21. The second trench part 32D extends from the first trench part 31D toward the second substrate surface 212 of the semiconductor substrate 21.

The first trench part 31A opens at the first substrate surface 211 of the semiconductor substrate 21. This first trench part 31A is considered a surface trench part. The first trench part 31B is disposed between the two second trench parts 32A and 32B arranged along the Z direction. This first trench part 31B is considered a middle trench part. The first trench part 31C is disposed between the two second trench parts 32B and 32C arranged along the Z direction. This first trench part 31C is considered a middle trench part. The first trench part 31D is disposed between the two second trench parts 32C and 32D arranged along the Z direction. This first trench part 31D may be considered a middle trench part.

The first trench parts 31A, 31B, 31C, and 31D extend in the z-axis direction. The first trench parts 31A, 31B, 31C, and 31D has first lengths D11A, D11B, D11C and D11D in the z-axis direction. In one example, the first lengths D11A to D11D are equal to each other. The first lengths D11A to D11D of the first trench parts 31A to 31D may be set such that at least one of them differs from others. The first lengths D11A to D11D of the first trench parts 31A to 31D may differ from each other.

The first trench parts 31A, 31B, 31C and 31D respectively have first widths W11A, W11B, W11C, and W11D in the x-axis direction, which is the width direction of the trench 30. In one example, the first widths W11A to W11D are equal to each other. The first widths W11A to W11D of the first trench parts 31A to 31D may be set such that at least one of them differs from others. The first widths W11A to W11D of the first trench parts 31A to 31D may differ from each other. The first width W11 of the first trench part 31 may be represented by the largest value among the first widths W11A to W11D of the plurality of first trench parts 31A to 31D. The first width W11 of the first trench part 31 may be represented by the average value of the first widths W11A to W11D of the plurality of first trench parts 31A to 31D.

The second trench parts 32A, 32B, 32C, and 32D extend in the z-axis direction. The second trench parts 32A, 32B, 32C, and 32D has second lengths D12A, D12B, D12C and D12D in the z-axis direction. In one example, the second lengths D12A to D12D are equal to each other. The second lengths D12A to D12D of the second trench parts 32A to 32D may be set such that at least one of them differs from others. The second lengths D12A to D12D of the second trench parts 32A to 32D may differ from each other.

The second trench parts 32A, 32B, 32C and 32D respectively have second widths W12A, W12B, W12C, and W12D in the x-axis direction, which is the width direction of the trench 30. In one example, the second widths W12A to W12D are equal to each other. The second widths W12A to W12D of the second trench parts 32A to 32D may be set such that at least one of them differs from others. The second lengths W12A to W12D of the second trench parts 32A to 32D may differ from each other.

The second width W12 of the second trench part 32 may be represented by the greatest value among the second widths W12A to W12D of the plurality of second trench parts 32A to 32D. The second width W12 of the second trench part 32 may be represented by the average value of the second widths W12A to W12D of the plurality of second trench parts 32A to 32D. It can be said that the second trench part 32 has the second width W12 that is greater than the first width W11 in the x-axis direction.

The inner surface 321 of the second trench part 32 includes side surfaces 322 that face each other in the x-axis direction, a top surface 323 that extends in the x-axis direction from the upper ends of the side surfaces 322, and a bottom surface 324 that extends in the x-axis direction from the lower ends of the side surfaces 322. Portions between the side surfaces 322 and the top surface 323 may be curved away from the second trench part 32. Portions between the side surfaces 322 and the bottom surface 324 may be curved away from the second trench part 32.

The trench 30 has a stepped surface between the first trench part 31 and the second trench part 32. More specifically, in the second trench parts 32A to 32D, the top surface 323 and the bottom surface 324 face each other in the z-axis direction. In the second trench parts 32A to 32D, the top surface 323 of the second trench part 32 connects the side surfaces 322 of the second trench part 32 to the inner surface 311 of the first trench part 31. The top surface 323 of the second trench part 32 constitutes the stepped surface between the second trench part 32 and the first trench part 31. In the second trench parts 32A to 32C, the bottom surface 324 of the second trench part 32 connects the side surfaces 322 of the second trench part 32 to the inner surface 311 of the first trench part 31. The bottom surface 324 of the second trench part 32 constitutes the stepped surface between the second trench part 32 and the first trench part 31.

In a plan view, the distance L21A between the inner surface 311 of the first trench part 31A and a side surface 322 of the second trench part 32A may correspond to the second length D12A of the second trench part 32A in the z-axis direction. The distance L21A may be the same as the second length D12A. The distance L21A may differ from the second length D12A.

In a plan view, the distance L21B between the inner surface 311 of the first trench part 31B and a side surface 322 of the second trench part 32B may correspond to the second length D12B of the second trench part 32B in the z-axis direction. The distance L21B may be the same as the second length D12B. The distance L21B may differ from the second length D12B.

In a plan view, the distance L21C between the inner surface 311 of the first trench part 31C and a side surface 322 of the second trench part 32C may correspond to the second length D12C of the second trench part 32C in the z-axis direction. The distance L21C may be the same as the second length D12C. The distance L21C may differ from the second length D12C.

In a plan view, the distance L21D between the inner surface 311 of the first trench part 31D and a side surface 322 of the second trench part 32D may correspond to the second length D12D of the second trench part 32D in the z-axis direction. The distance L21D may be the same as the second length D12D. The distance L21D may differ from the second length D12D.

### (Insulating Layer)

The insulating layer 40 includes a first insulating layer 41 that covers the inner surface 311 of the first trench part 31, and a second insulating layer 42 that covers the inner surface 321 of the second trench part 32. The thickness of the first insulating layer 41 may be the same as the thickness of the second insulating layer 42. The thickness of the first insulating layer 41 may differ from the thickness of the second insulating layer 42.

The first trench part 31A as the surface trench part opens at the first substrate surface 211 of the semiconductor substrate 21. The surface insulating layer 22 formed on the first substrate surface 211 of the semiconductor substrate 21 has an opening 223 that connects to the trench 30. The insulating layer 40 may include an extended portion 43 located in the opening 223 of the surface insulating layer 22.

### (Electrode Part)

The electrode part 50 includes a first electrode part 51 inside the first trench part 31 and a second electrode part 52 inside the second trench part 32. The first electrode part 51 and the second electrode part 52 are electrically connected to each other. The electrode part 50 may include a connection portion 53 disposed in the opening 223 of the surface insulating layer 22. The connection portion 53 is surrounded by the extended portion 43 of the insulating layer 40 in a plan view. The connection portion 53 is exposed from the surface insulating layer 22. The connection portion 53 is electrically connected to a wiring component such as via wiring, which is not shown in the figure. The electrode part 50 is electrically connected to the circuit elements in the semiconductor device 10 through the connection portion 53.

### (Hollow)

The second trench part 32 includes a hollow 35 (seam). The hollow 35 is surrounded by the second electrode part 52. It can be said that the hollow 35 is an area that is not filled with the electrode part 50 inside the insulating layer 42 of the second trench part 32. Thus, it can be said that electrode part 50 disposed in the second trench part 32 has a hollow shape.

As illustrated in FIG. 3, the plurality of trenches 30 are arranged along the x-axis direction, separated from each other. The interval between the plurality of trenches 30 may be indicated by the distance L31 between two first trench parts 31 arranged along the x-axis direction, which is the arrangement direction. The interval between the plurality of trenches 30 may also be indicated by the distance L32 between two second trench parts 32 arranged along the x-axis direction. The distance L32 between two second trench parts 32 adjacent to each other in x-axis direction is smaller than the second width W12 (W12A to W12D) of the second trench part 32.

### (Manufacturing Method of Semiconductor Device)

Next, an example of the manufacturing method of the semiconductor device 10 of FIGS. 1 to 4 will be explained.

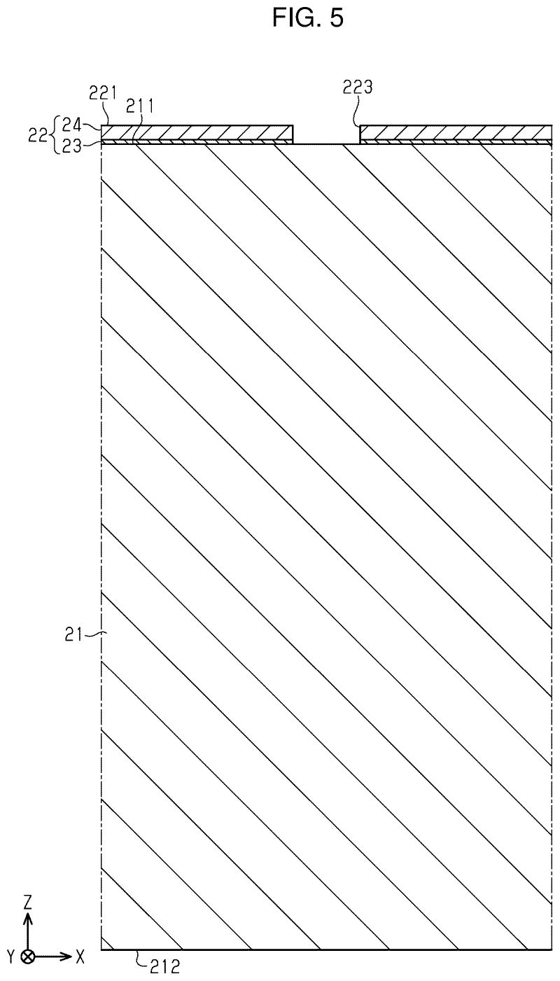

FIGS. 5 to 17 are schematic cross-sectional views showing an illustrative manufacturing process of the semiconductor device 10. FIGS. 5 to 17 correspond to the cross-sectional structure of the semiconductor device 10 illustrated in FIG. 4. FIGS. 5 to 17 illustrates the scope to create the configurations for one trench 30. For ease of understanding, in FIGS. 5 to 17, the same components as the final components of the semiconductor device 10 are given the same reference characters as those of FIG. 4.

As shown in FIG. 5, the manufacturing method of the semiconductor device 10 includes preparing the semiconductor substrate 21. The semiconductor substrate 21 may be a silicon wafer including a first conductive type impurity, for example. The semiconductor substrate 21 has a first substrate surface 211 and a second substrate surface 212 on the opposite side to the first substrate surface 211.

The manufacturing method of the semiconductor device 10 includes forming the surface insulating layer 22 on the first substrate surface 211 of the semiconductor substrate 21. The surface insulating layer 22 has an opening 223 that exposes the first substrate surface 211 of the semiconductor substrate 21 at a position where the trench 30 is to be formed (see FIG. 4).

The surface insulating layer 22 may be made of a material containing Si. The surface insulating layer 22 may have a multi-layer structure. The surface insulating layer 22 may be constituted of a single layer. In one example, the surface insulating layer 22 includes a first insulating layer 23 and a second insulating layer 24 laminated in this order from the first substrate surface 211 of the semiconductor substrate 21. The first insulating layer 23 and the second insulating layer 24 may be insulating films. The first insulating layer 23 may be a SiN film, and the second insulating layer 24 may be an SiO₂ film.

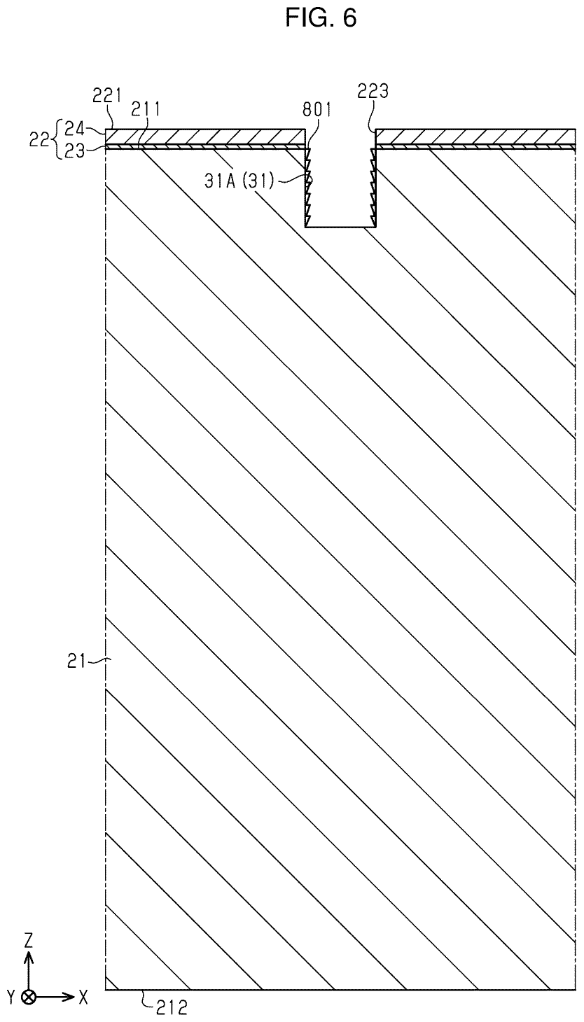

As illustrated in FIGS. 6 to 12, the manufacturing method of the semiconductor device 10 includes forming a trench 30. The trench 30 includes a plurality of first trench parts 31A to 31D and second trench parts 32A to 32D.

First, formation of the first trench part 31A and the second trench part 32A will be explained.

As illustrated in FIGS. 6, the manufacturing method of the semiconductor device 10 includes forming the first trench part 31A. The first trench part 31A is formed by deep-etching the semiconductor substrate 21. In the deep-etching, isotropic etching of Si using F radicals and anisotropic etching are alternately repeated in general. On the inner surface 311 of the first trench part 31A, a protective film 801 can be formed by the deep-etching. This protective film 801 is formed by conformal CVD using CF gas, for example.

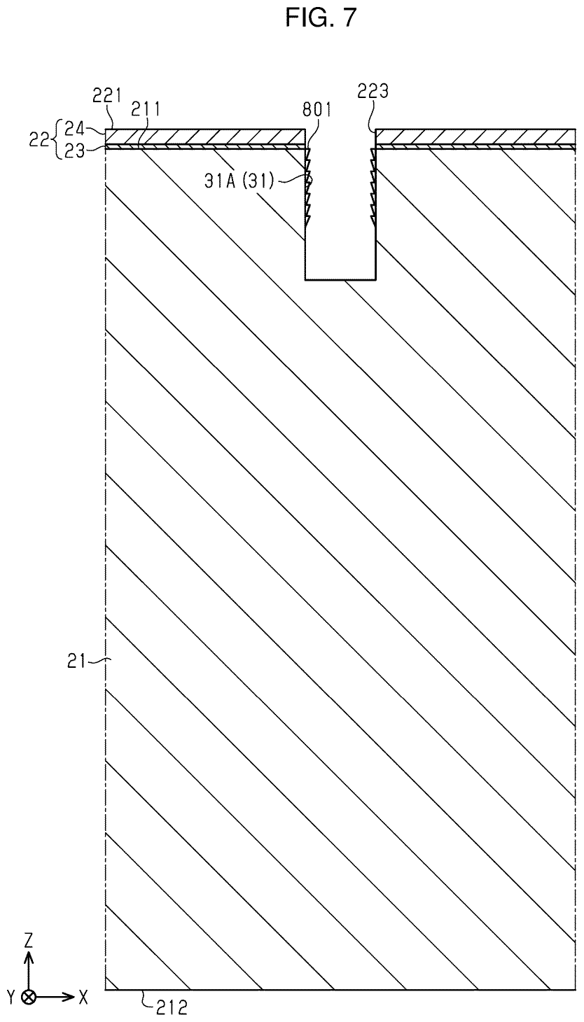

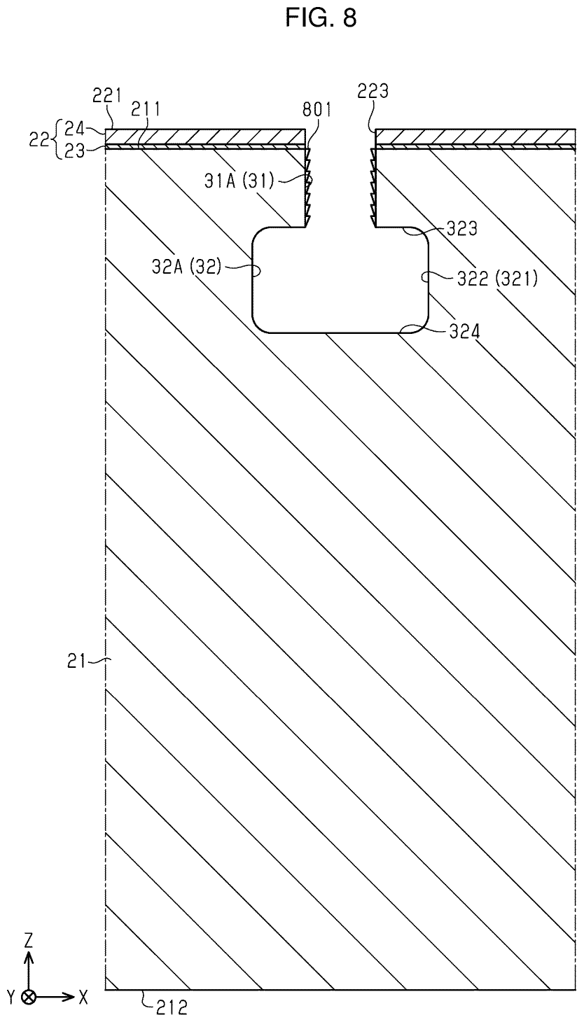

As illustrated in FIGS. 7 and 8, the manufacturing method of the semiconductor device 10 includes forming the second trench part 32A. The second trench part 32A is formed by isotropic etching, for example. The second trench part 32A is formed under the first trench part 31A by performing isotropic etching of Si using F radicals, for example, on a portion of the semiconductor substrate 21 exposed from the first trench part 31A. By isotropic etching, the semiconductor substrate 21 is etched from the lower end of the first trench part 31A in the z-axis direction, as well as in the X-axis and Y-axis directions. This way, the second trench part 32A having the second width W12 that is greater than the first width W11 of the first trench part 31A is formed.

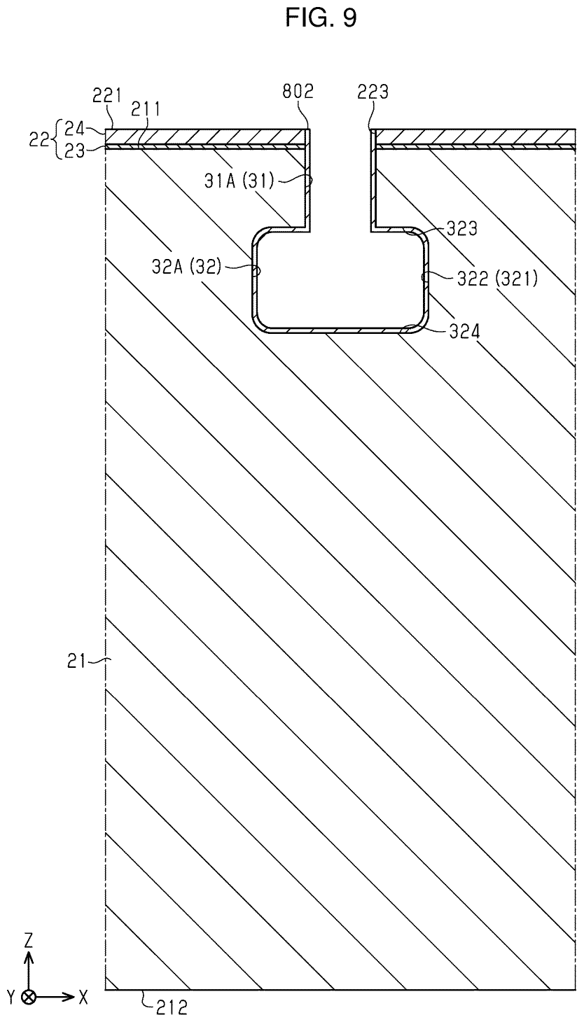

As illustrated in FIG. 9, the manufacturing method of the semiconductor device 10 includes forming an oxide film 802 on the inner surface 311 of the first trench part 31A and the inner surface 321 of the second trench part 32A.

First, the protective film 801 (see FIG. 8) on the inner surface 311 of the first trench part 31A is removed. Next, the oxide film 802 is formed on the inner surface 311 of the first trench part 31A and the inner surface 321 of the second trench part 32A. The oxide film 802 is formed through thermal oxidation of Si, for example.

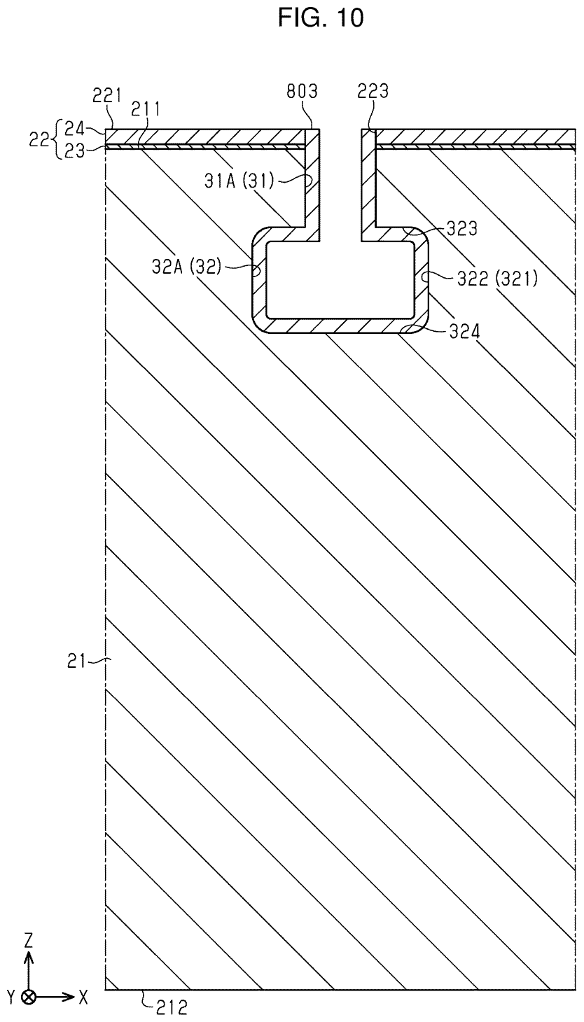

As illustrated in FIG. 10, the manufacturing method of the semiconductor device 10 includes forming an oxide film 803. The oxide film 803 is obtained by depositing a silicon oxide film on the oxide film 802 illustrated in FIG. 9. The silicon oxide film can be formed by a plasma CVD method using TEOS (tetra ethoxy silane) as a material, for example. The silicon oxide film may be an LP (low pressure)-TEOS oxide film.

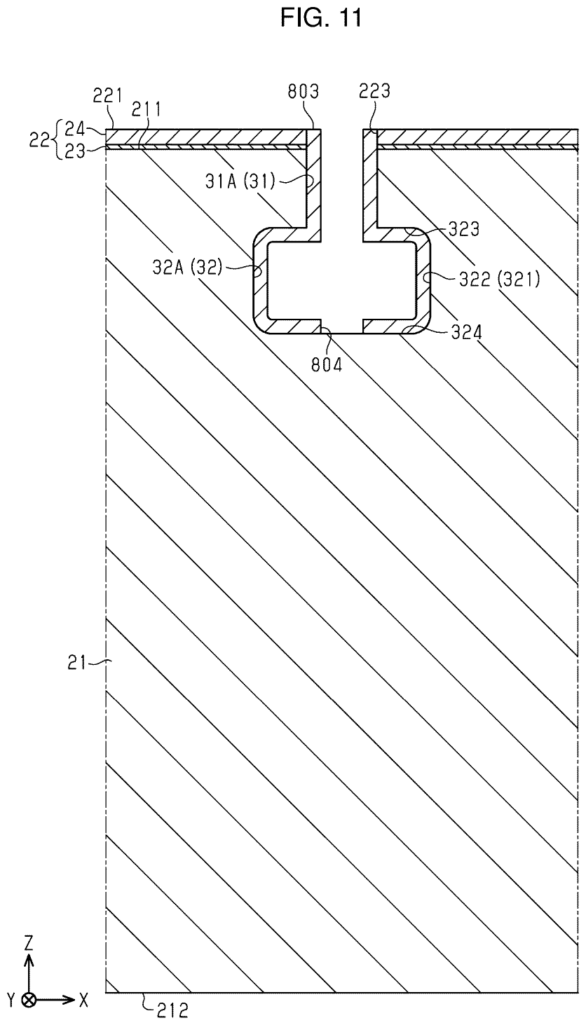

As illustrated in FIG. 11, the manufacturing method of the semiconductor device 10 includes forming an opening 804 that exposes the semiconductor substrate 21. The opening 804 is formed by removing a part of the oxide film 803 that covers the inner surface 321 of the second trench part 32A by etching. The opening 804 is formed by performing isotropic etching on a part of the oxide film 803 that covers the bottom surface 324 of the second trench part 32A, out of the oxide film 803 that covers the inner surface 321 of the second trench part 32A.

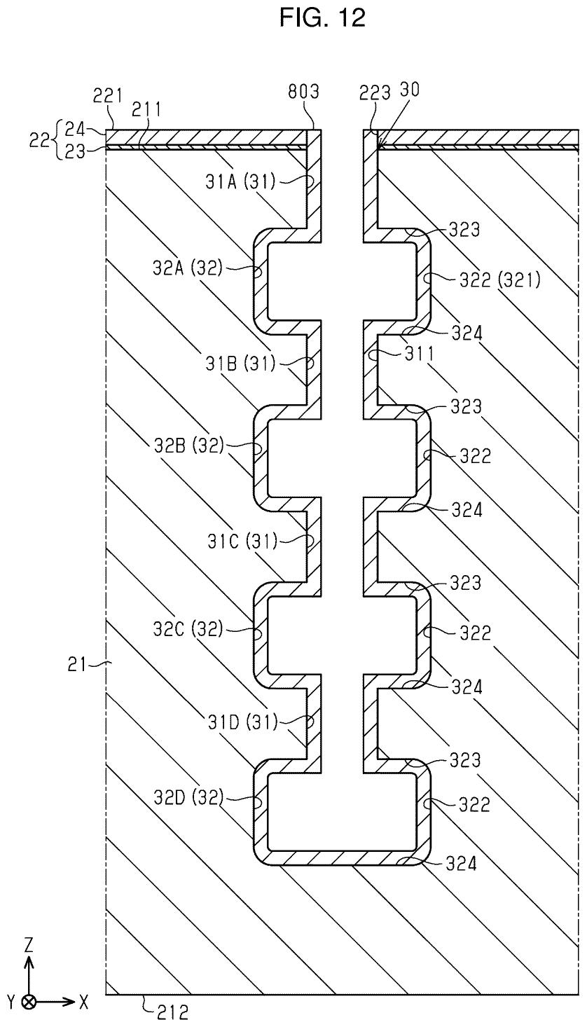

As illustrated in FIG. 12, the manufacturing method of the semiconductor device 10 includes forming a plurality of first trench parts 31B to 31D and a plurality of second trench parts 32B to 32D. The plurality of first trench parts 31B to 31D can be formed in a manner similar to the first trench part 31A. The plurality of second trench parts 32B to 32D can be formed in a manner similar to the second trench part 32A. That is, the plurality of first trench parts 31B to 31D and the plurality of second trench parts 32B to 32D are formed by alternately repeating the step of forming the first trench part 31A and the step of forming the second trench part 32A described above.

Through the steps described above, the trench 30 is formed.

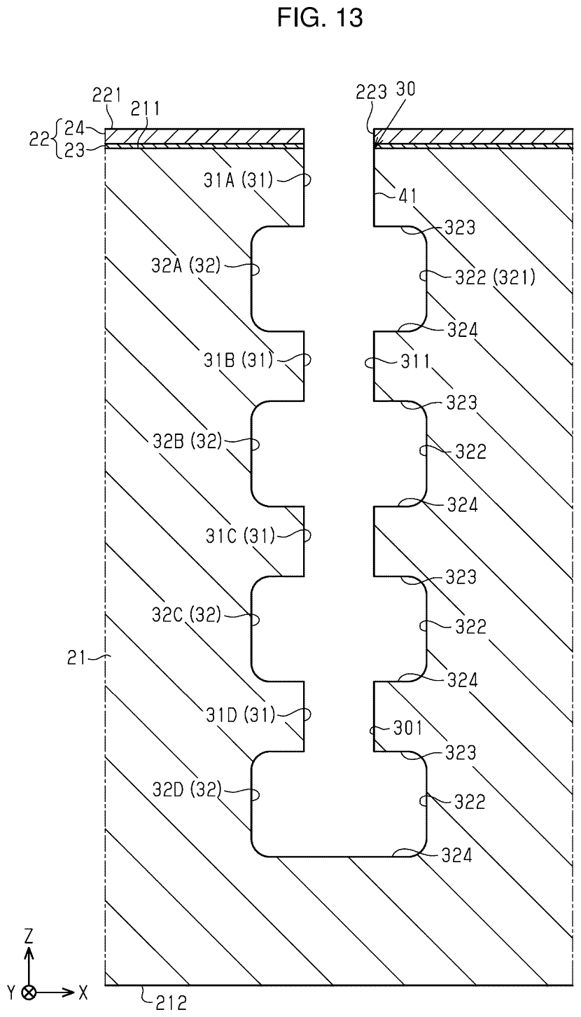

As illustrated in FIG. 13, the manufacturing method of the semiconductor device 10 includes removing the oxide film 803. The oxide film 803 may be removed by HF (hydrofluoric acid), for example.

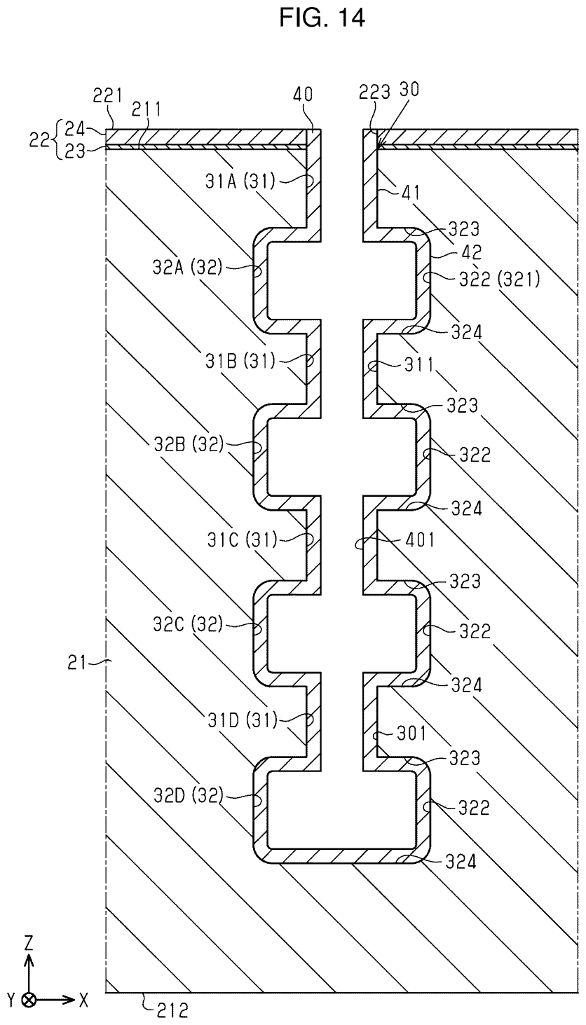

As illustrated in FIG. 14, the manufacturing method of the semiconductor device 10 includes forming the insulating layer 40 on the inner surface 301 of the trench 30. The insulating layer 40 may be made of a material containing Si. In one example, the insulating layer 40 may be an oxide film containing Si. This insulating layer 40 may be formed through thermal oxidation of Si, for example.

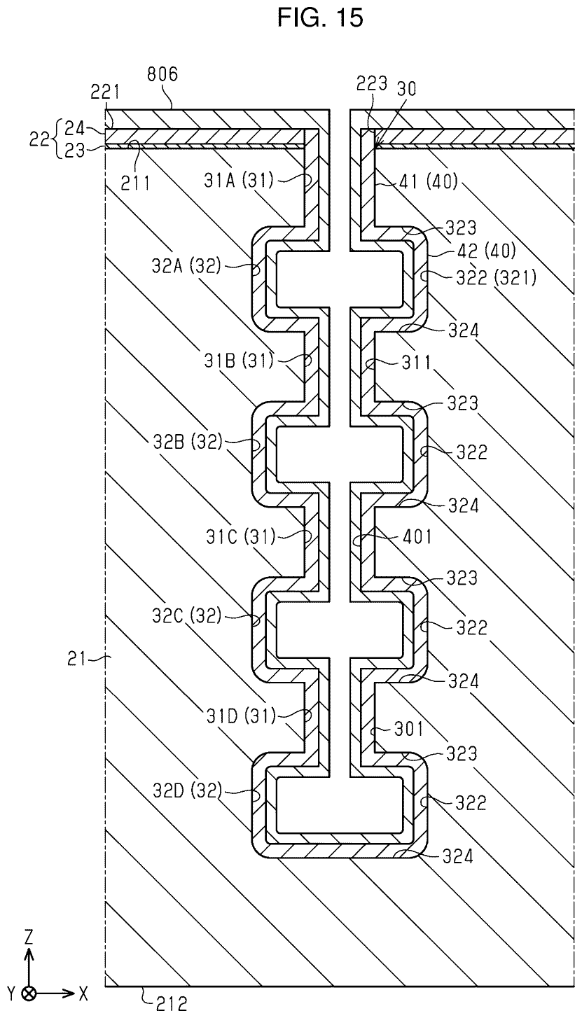

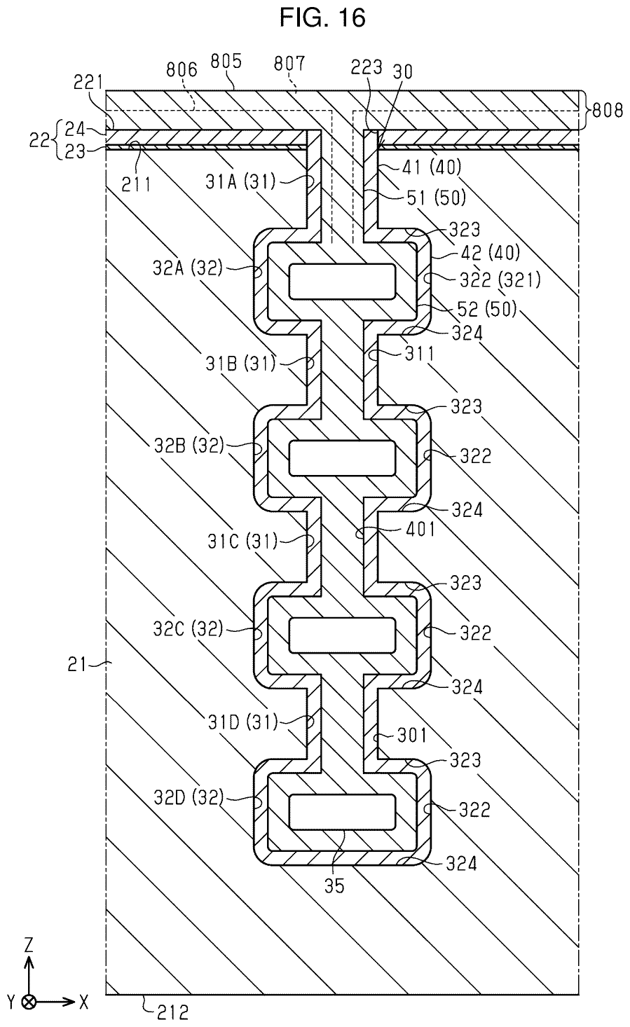

As illustrated in FIGS. 15 and 16, the manufacturing method of the semiconductor device 10 includes forming the conductive layer 805. The conductive layer 805 may be formed of polysilicon. In one example, the conductive layer 805 may include a first polysilicon layer 806 and a second polysilicon layer 807. In FIG. 16, the dashed line is partially drawn to distinguish the first polysilicon layer 806 from the second polysilicon layer 807.

As illustrated in FIG. 15, the first polysilicon layer 806 is formed on the inner surface 401 of the insulating layer 40. The first polysilicon layer 806 may be a non-doped polysilicon without added impurity. The first polysilicon layer 806 may be formed by the CVD method. The first polysilicon layer 806 is formed to cover the top surface 221 of the surface insulating layer 22. Next, the second polysilicon layer 807 is formed. The second polysilicon layer 807 may be a doped polysilicon with added impurity. The second polysilicon layer 807 may be formed by the CVD method. The second polysilicon layer 807 is formed to fill up the first trench part 31. This completes the conductive layer 805. The conductive layer 805 is formed to cover the top surface 221 of the surface insulating layer 22.

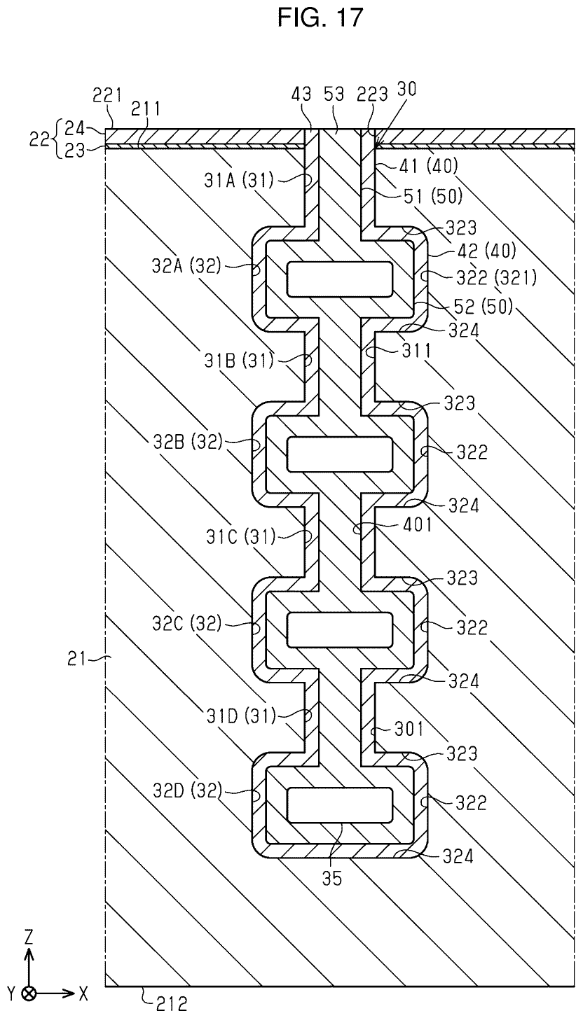

As illustrated in FIG. 17, the manufacturing method of the semiconductor device 10 includes forming the electrode part 50. The electrode part 50 is formed by removing a part 808 of the conductive layer 805 illustrated in FIG. 16 that is above the top surface 221 of the surface insulating layer 22. The portion 808 on the top surface 221 of the surface insulating layer 22 is removed by CMP (chemical mechanical polishing), for example.

### Comparison Example

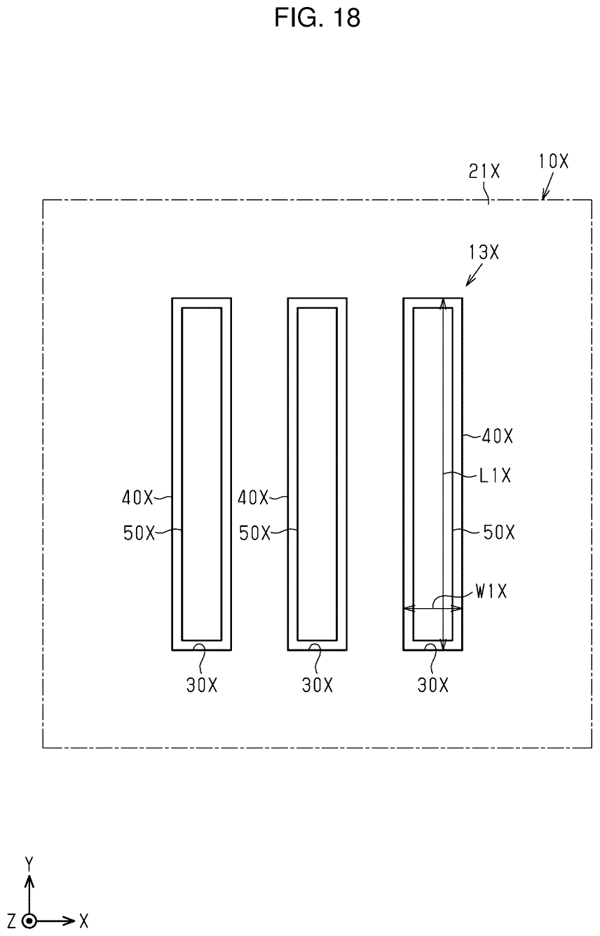

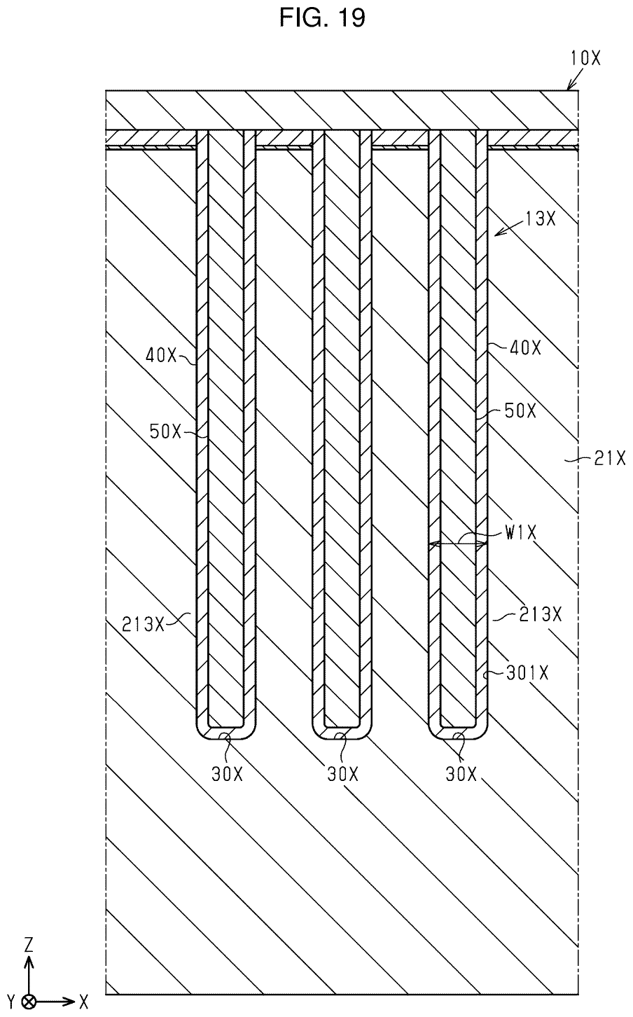

FIG. 18 is a schematic plan view showing a part of a semiconductor device 10X of a comparison example. FIG. 18 corresponds to a schematic plan view of the semiconductor device 10 of FIG. 2. FIG. 19 is a schematic cross-sectional view of the semiconductor device 10X of FIG. 18. FIG. 19 corresponds to a schematic cross-sectional view of the semiconductor device 10 of FIG. 3. For the semiconductor device 10X of the comparison example of FIGS. 18 and 19, the components corresponding to those of the semiconductor device 10 of FIGS. 1 to 4 are given the same names and reference characters.

The semiconductor device 10X of the comparison example includes a plurality of trenches 30X. The plurality of trenches 30X are arranged along the x-axis direction, separated from each other. Each trench 30X extends along the y-axis direction. Each trench 30X has a width W1X in the x-axis direction. The trench 30X has the width W1X that is mostly constant from the opening edge of the trench 30X to the bottom of the trench 30X.

The electrode part 50X disposed in the trench 30X faces the inner surface 301X of the trench 30X across the insulating layer 40X, or in other words, faces a wall part 213X of the semiconductor substrate 21X. A capacitor 13X of a comparison example is constituted of the wall part 213X of the semiconductor substrate 21X and the electrode part 50X facing each other across the insulating layer 40X.

### Actions of Embodiments

As illustrated in FIGS. 3 and 4, the semiconductor device 10 includes a semiconductor substrate 21, a trench 30, an insulating layer 40, and an electrode part 50. The semiconductor substrate 21 has a first substrate surface 211 and a second substrate surface 212 on the opposite side to the first substrate surface 211. The trench 30 is recessed from the first substrate surface 211 toward the second substrate surface 212, and has a width W1A in a plan view. The insulating layer 40 is disposed on the inner surface 301 of the trench 30. The electrode part 50 is disposed inside the trench 30 and surrounded by the insulating layer 40. The electrode part 50 has conductivity. The trench 30 includes a first trench part 31 and a second trench part 32. The first trench part 31 has a first width W11 in the width direction of the trench 30. The second trench part 32 is disposed at a location differing from the first trench part 31 in a z-axis direction. The second trench part 32 has a second width W12 that is greater than the first width W11 in the width direction of the trench 30.

The electrode part 50 disposed in the trench 30 faces the inner surface 301 of the trench 30 across the insulating layer 40 or in other words, faces a wall part 213 of the semiconductor substrate 21. A capacitor 13 is constituted of the wall part 213 of the semiconductor substrate 21 and the electrode part 50 facing each other across the insulating layer 40.

The trench 30 includes the first trench part 31 and the second trench part 32 having the second width W12 that is greater than the first width W11 of the first trench part 31. The inner surface 301 of the trench 30 has a greater area than that of the inner surface 301X of the trench 30X of the comparison example. Thus, it is possible to increase the capacity of the capacitor 13 constituted of the insulating layer 40 and the electrode part 50 disposed in the trench 30.

### Effects of Embodiments

As described above, according to the semiconductor device 10 of an embodiments of the present disclosure, the following effects are achieved.
(1) A semiconductor device 10 includes a semiconductor substrate 21, a trench 30, an insulating layer 40, and an electrode part 50. The semiconductor substrate 21 has a first substrate surface 211 and a second substrate surface 212 on the opposite side to the first substrate surface 211. The trench 30 is recessed from the first substrate surface 211 toward the second substrate surface 212, and has a width W1A in a plan view. The insulating layer 40 is disposed on the inner surface 301 of the trench 30. The electrode part 50 is disposed inside the trench 30 and surrounded by the insulating layer 40. The electrode part 50 has conductivity. The trench 30 includes a first trench part 31 and a second trench part 32. The first trench part 31 has a first width W11 in the width direction of the trench 30. The second trench part is disposed at a location differing from the first trench part 31 in the z-axis direction. The second trench part 32 has a second width W12 that is greater than the first width W11 in the width direction of the trench 30.

The electrode part 50 disposed in the trench 30 faces the inner surface 301 of the trench 30 across the insulating layer 40 or in other words, faces a wall part 213 of the semiconductor substrate 21. A capacitor 13 is constituted of the wall part 213 of the semiconductor substrate 21 and the electrode part 50 facing each other across the insulating layer 40. It is possible to increase the capacity of this capacitor 13.
(2) The second trench part 32 has the second width W12 that is greater than the first width W11 of the first trench part 31. Because the second width W12 of the second trench part 32 is greater than the first width W11 of the first trench part 31, the area of the inner surface 301 of the trench 30 increases. That is, it is possible to increase the area of the inner surface 301 of the trench 30, or in other words, the capacity of the capacitor 13 by adjusting the second width W12 of the second trench part 32.
(3) The trench 30 includes a plurality of first trench parts 31 and a plurality of second trench parts 32. The plurality of first trench parts 31 and the plurality of second trench parts 32 are alternately arranged along the thickness direction of the semiconductor substrate 21. Thus, it is possible to increase the area of the inner surface 301 of the trench 30, or in other words, the capacity of the capacitor 13 by adjusting the number of the second trench parts 32.

### Modification Examples

The embodiments described above may be modified in the following manner, for example. The embodiments described above and the respective modification examples may be combined with each other unless such a combination results in technological contradiction. In the following modification examples, parts common to the above embodiments will be given the same reference characters as the above embodiments and descriptions thereof will be omitted.

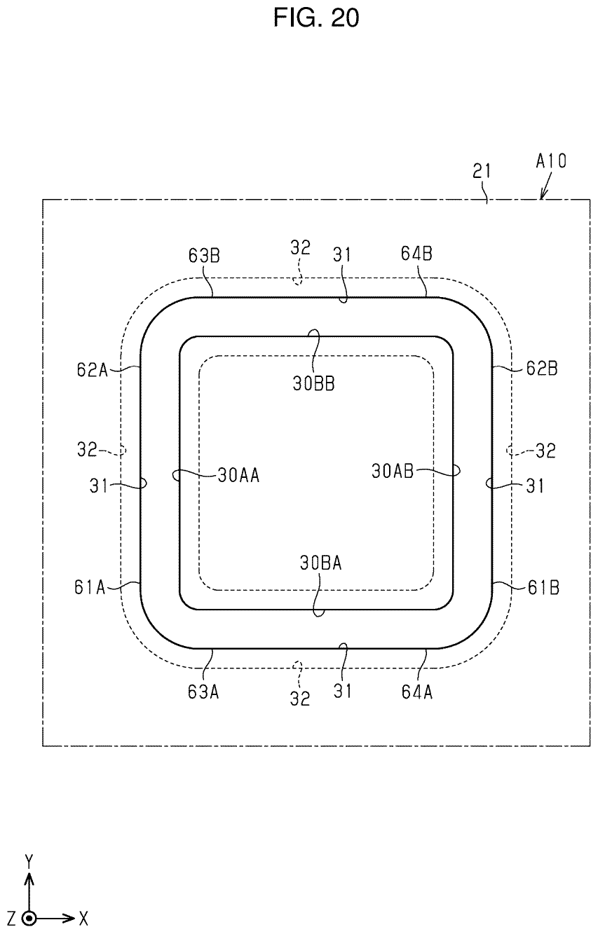

FIG. 20 is a schematic plan view showing a semiconductor device A10 of a modification example. The semiconductor device A10 includes two first trenches 30AA and 30AB, and two second trenches 30BA and 30BB. The first trenches 30AA and 30AB extend in the first direction when viewed from the z-axis direction. In one example, the first direction may be the y-axis direction. The second trenches 30BA and 30BB extend in the second direction that intersects with the first direction when viewed from the z-axis direction. In one example, the second direction may be a direction orthogonal to the first direction. The second direction may be the x-axis direction.

The first trenches 30AA and 30AB and the second trenches 30BA and 30BB include four first trench parts 31 and four second trench parts 32. The first trenches 30AA and 30AB and the second trenches 30BA and 30BB may include at least one first trench part 31 and at least one second trench part 32.

In the semiconductor device A10 illustrated in FIG. 20, the first trenches 30AA, 30AB and the second trenches 30BA, 30BB are connected with each other.

The first trenches 30AA, 30AB include first end portions 61A, 61B in the y-axis direction and second end portions 62A, 62B at the opposite end to the first end portions 61A, 61B. The second trenches 30BA, 30BB include first end portions 63A, 63B in the x-axis direction and second end portions 64A, 64B at the opposite end to the first end portions 63A, 63B. The first end portion 61A of the first trench 30AA is connected to the first end portion 63A of the second trench 30BA, and the second end portion 62A of the first trench 30AA is connected to the first end portion 63B of the second trench 30BB. The first end portion 61B of the first trench 30AB is connected to the second end portion 64A of the second trench 30BA, and the second end portion 62B of the first trench 30AB is connected to the second end portion 64B of the second trench 30BB.

As a result, the first trenches 30AA, 30AB and the second trenches 30BA, 30BB form a rectangular shape when viewed from the z-axis direction.

The first trenches 30AA, 30AB and the second trenches 30BA, 30BB may be separated from each other. For example, both of the two second trenches 30BA, 30BB may be separated from the first trenches 30AA, 30AB. Alternatively, the second trench 30BB may be separated from the first trenches 30AA, 30AB, and the second trench 30BA may be connected to the first trenches 30AA, 30AB, for example.

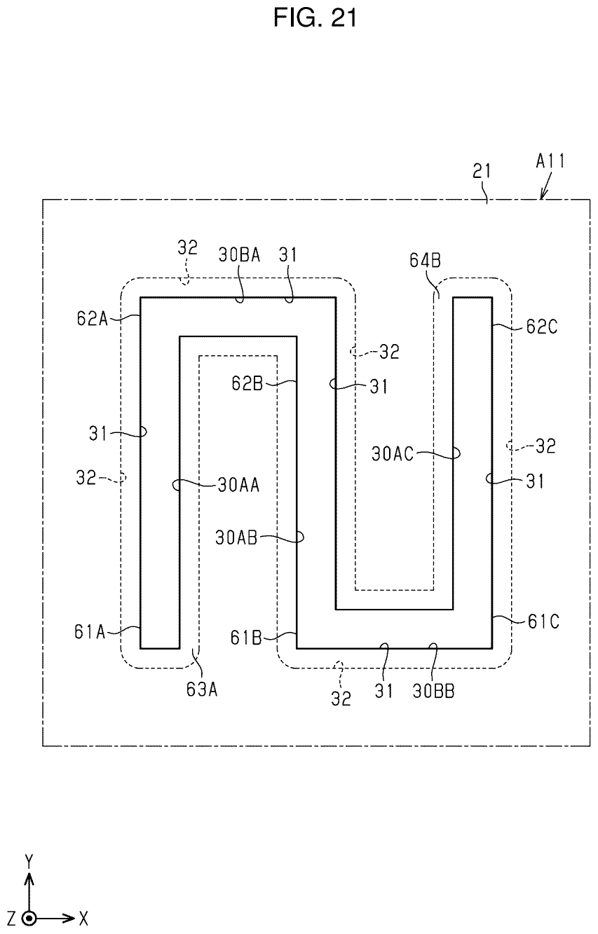

FIG. 21 is a schematic plan view showing a semiconductor device A11 of a modification example. The semiconductor device A11 includes three first trenches 30AA, 30AB and 30AC, and two second trenches 30BA and 30BB.

The first trenches 30AA, 30AB, and 30AC and the second trenches 30BA and 30BB include four first trench parts 31 and four second trench parts 32. The first trenches 30AA, 30AB, and 30AC and the second trenches 30BA and 30BB may include at least one first trench part 31 and at least one second trench part 32.

The first trenches 30AA, 30AB and 30AC extend in the y-axis direction when viewed from the z-axis direction. The first trenches 30AA, 30AB, and 30AC include first end portions 61A, 61B, and 61C in the y-axis direction and second end portions 62A, 62B, and 62C at the opposite end to the first end portions 61A, 61B, and 61C. The second end portions 62A and 62B of the first trench 30AA, 30AB are connected to the second trench 30BA. The first end portions 61B and 61C of the first trench 30AB, 30AC are connected to the second trench 30BB.

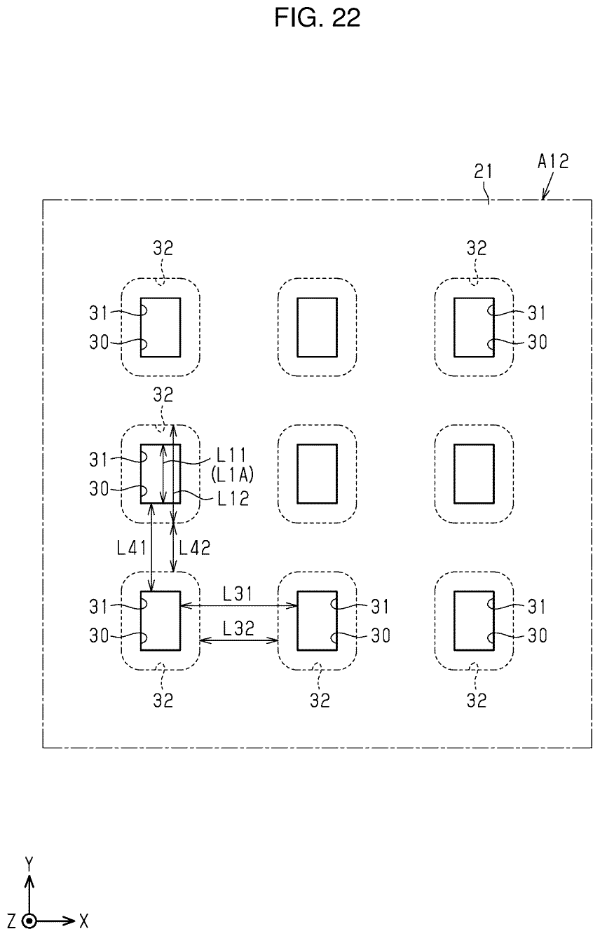

FIG. 22 is a schematic plan view showing a semiconductor device A12 of a modification example. The semiconductor device A12 includes a plurality of trenches 30. The plurality of trenches 30 are arranged along the x-axis direction and y-axis direction, separated from each other. In one example, each of the trenches 30 is elongated along the y-axis direction in a plan view.

The plurality of trenches 30 are arranged along the y-axis direction at a first interval. The first interval may be indicated by the distance L42 between two second trench parts 32 adjacent to each other along the y-axis direction. The first interval may be indicated by the distance L41 between two first trench parts 31 adjacent to each other along the y-axis direction.

The plurality of trenches 30 are arranged along the x-axis direction at a second interval. The second interval may be indicated by the distance L32 between two second trench parts 32 adjacent to each other along the x-axis direction. The second interval may be indicated by the distance L31 between two first trench parts 31 adjacent to each other along the x-axis direction.

Each of the trenches 30 has a length L1A in the y-axis direction. The first trench part 31 has a length L11 in the y-axis direction. The second trench part 32 has a length L12 in the y-axis direction. In one example, the length L1A of the trench 30 in the y-axis direction may be represented by the length L12 of the second trench part 32 in the y-axis direction. The distance L42 indicated by the first interval between two trenches 30 adjacent to each other in y-axis direction is smaller than the length L12 of the second trench part 32.

Each of the trenches 30 includes four first trench parts 31 and four second trench parts 32. Each of the trenches 30 may include at least one first trench part 31 and at least one second trench part 32.

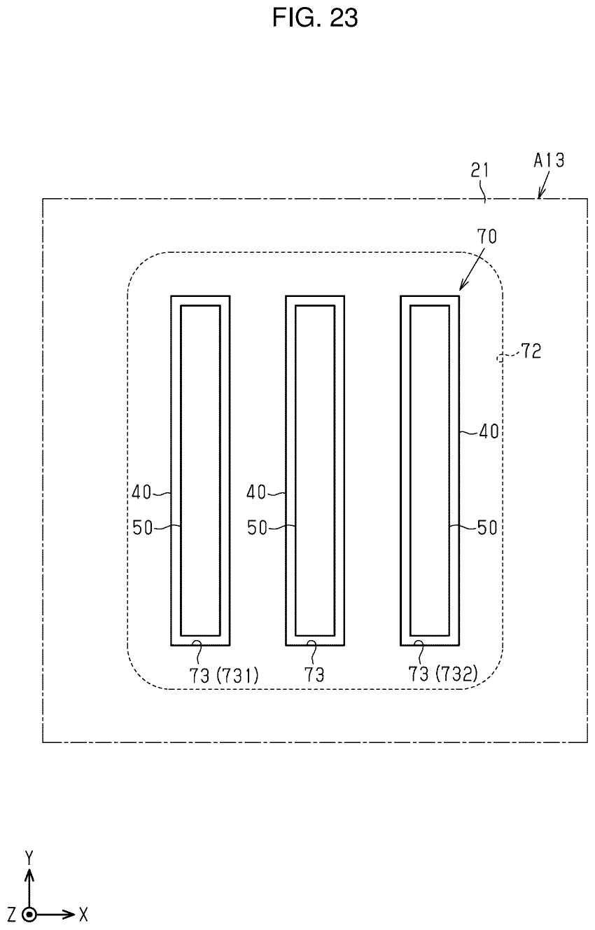

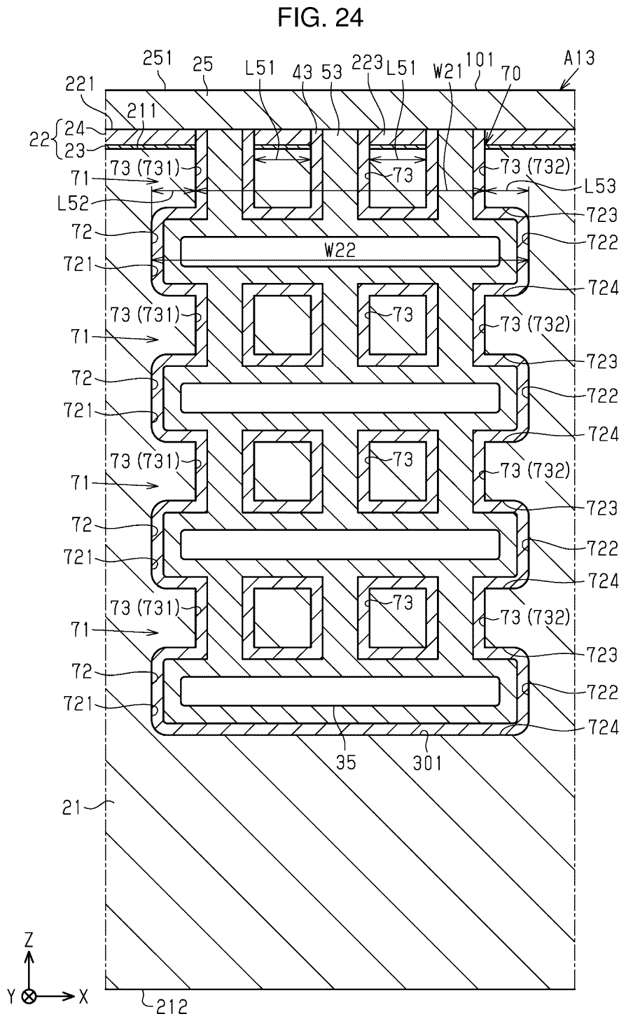

FIG. 23 is a schematic plan view showing a semiconductor device A13 of a modification example. FIG. 24 is a schematic cross-sectional view of the semiconductor device A13 of FIG. 23.

The semiconductor device A13 includes a trench 70 formed in the semiconductor substrate 21.

The trench 70 includes four first trench parts 71 and four second trench parts 72. The four first trench parts 71 and four second trench parts 72 are alternately arranged along the z-axis direction. The four first trench parts 71 and four second trench parts 72 are connected with each other in the z-axis direction. The number of the first trench parts 71 may be modified to any number that is one or greater. The number of the second trench parts 72 may be modified to any number that is one or greater.

The first trench part 71 that opens at the first substrate surface 211 of the semiconductor substrate 21 is considered the surface trench part. This first trench parts 71 between the second trench parts 72 in the z-axis direction are considered the middle trench parts.

The first trench part 71 has three holes 73 extending in the z-axis direction and arranged along the width direction, or the x-axis direction in this example. The number of holes 73 may be two or four or more.

As illustrated in FIG. 23, the plurality of holes 73 are arranged along the x-axis direction, separated from each other. The plurality of holes 73 may be arranged at an even interval. In one example, the plurality of holes 73 are arranged at an interval that is equal to the distance L51 between two holes 73 adjacent to each other in the x-axis direction. The plurality of holes 73 extend in the y-axis direction when viewed from the z-axis direction. The plurality of holes 73 include a first hole 731 and a second hole 732 disposed at respective ends in the x-axis direction along which the holes are arranged.

The second trench part 72 include a first side surface 721 and a second side surface 722 that face each other in the x-axis direction. The second trench part 72 includes a top surface 723 located closer to the first substrate surface 211 of the semiconductor substrate 21, and a bottom surface 724 located closer to the second substrate surface 212 of the semiconductor substrate 21. The top surface 723 and the bottom surface 724 constitute the stepped surface between the second trench part 72 and the first trench part 71. Portions between the side surfaces 721, 722 and the top surface 723 may be curved away from the second trench part 72. Portions between the side surfaces 721, 722 and the bottom surface 724 may be curved away from the second trench part 72.

As opposed to the second trench part 72, the first trench part 71 (holes 73) located closer to the first substrate surface 211 of the semiconductor substrate 21 opens at the top surface 723 of the second trench part 72. As opposed to the second trench part 72, the first trench part 71 (hole 73) located closer to the second substrate surface 212 of the semiconductor substrate 21 opens at the bottom surface 724 of the second trench part 72. Thus, the second trench part 72 straddles a plurality of holes 73. Also, the second trench part 72 runs through the plurality of holes 73.

The first side surface 721 of the second trench part 72 is located on the opposite side of the first hole 731 to the second hole 732. The second side surface 722 of the second trench part 72 is located on the opposite side of the first hole 731 to the second hole 732. That is, the first side surface 721 and the second side surface 722 of the second trench part 72 are located at the positions that sandwich the three holes 73 of the first trench part 71 in the x-axis direction in a plan view. The second width W22 of the second trench part 72 is greater than the first width W21 of the first trench part 71 that includes the three holes 73.

In a plan view, the distance L52 from the first hole 731 to the first side surface 721 of the second trench part 72 may be equal to the distance L53 from the second hole 732 to the second side surface 722 of the second trench part 72. In a plan view, the distance L51 between the holes 73 is smaller than twice the distance L52 from the first hole 731 to the side surface 721 of the second trench part 72. The distance L51 between the holes 73 may be equal to or greater than the distance L52 from the first hole 731 to the first side surface 721 of the second trench part 72.

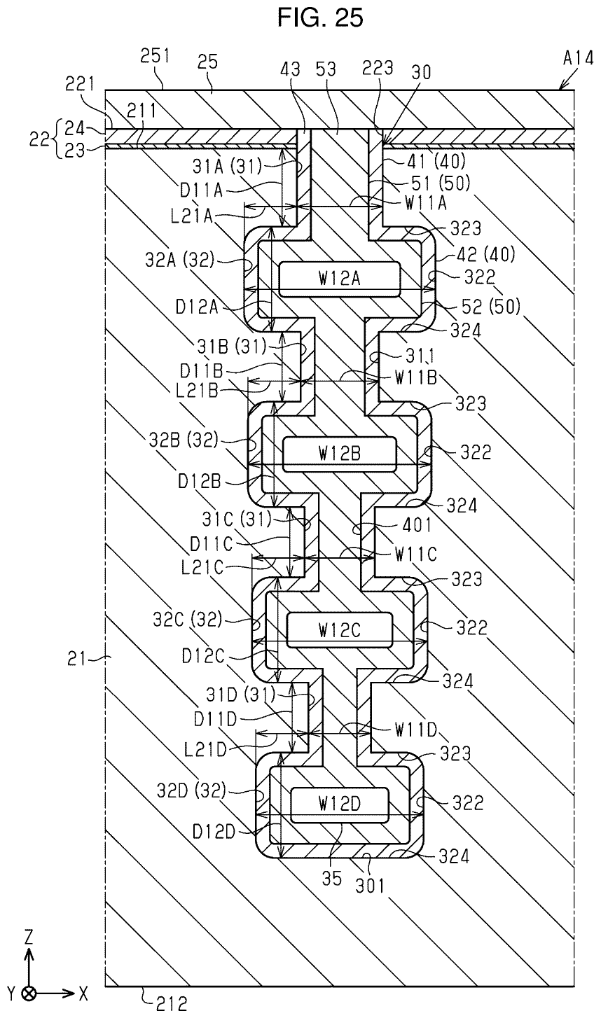

FIG. 25 is a schematic cross-sectional view showing a semiconductor device A14 of a modification example. In this semiconductor device A14, the first trench parts 31A to 31D may be disposed such that the respective first widths W11A to W11D differ from each other. In the semiconductor device A14, the first trench parts 31A to 31D are disposed such that the first widths W11A to W11D become smaller from the first substrate surface 211 toward the second substrate surface 212 of the semiconductor substrate 21.

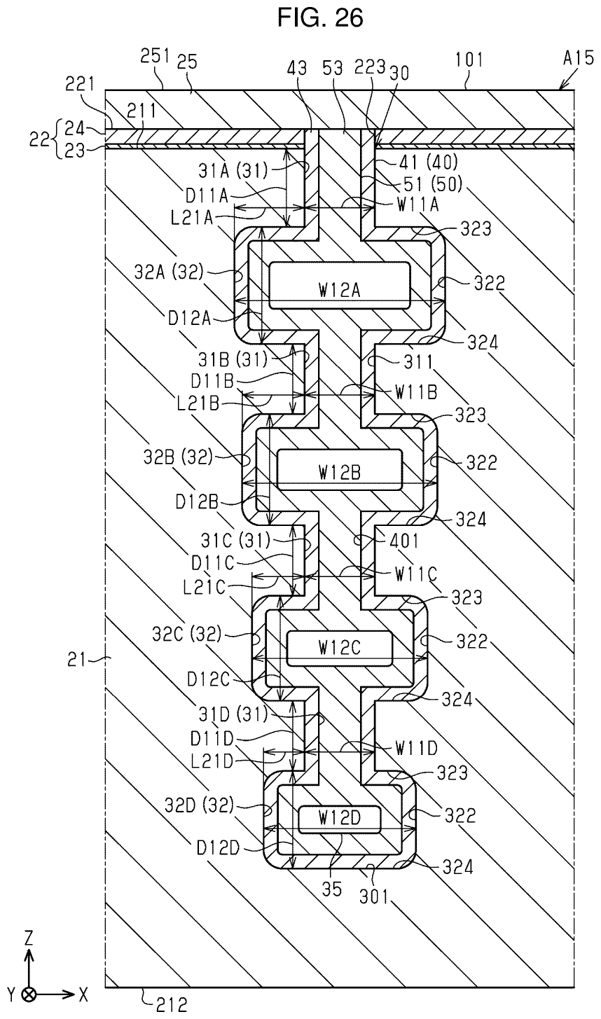

FIG. 26 is a schematic cross-sectional view showing a semiconductor device A15 of a modification example. In this semiconductor device A15, the second trench parts 32A to 32D may be disposed such that the respective second widths W12A to W12D differ from each other. In the semiconductor device A15, the second trench parts 32A to 32D are disposed such that the second widths W12A to W12D become smaller from the first substrate surface 211 toward the second substrate surface 212 of the semiconductor substrate 21.

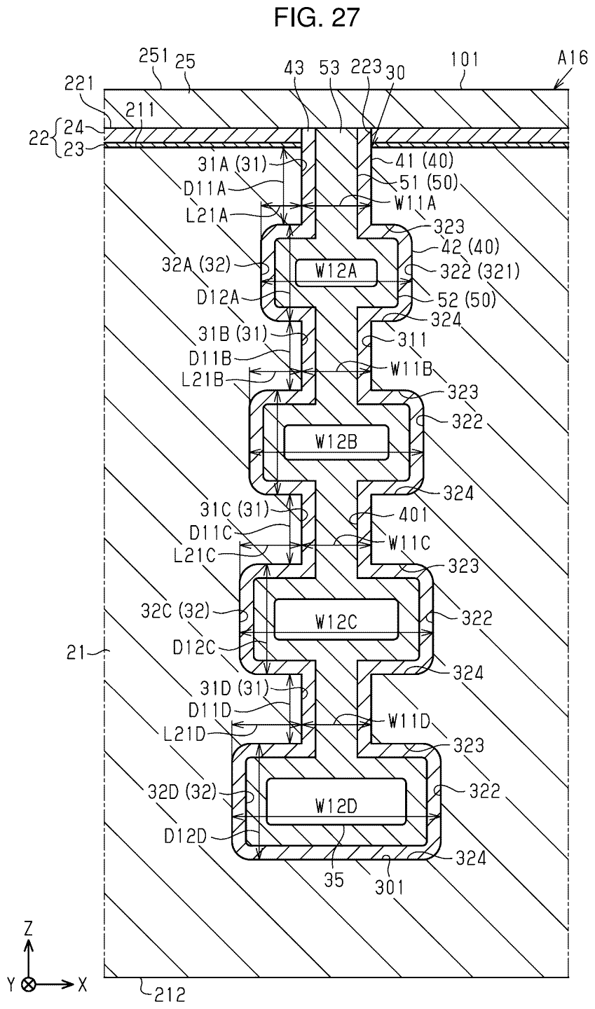

FIG. 27 is a schematic cross-sectional view showing a semiconductor device A16 of a modification example. In this semiconductor device A16, the second trench parts 32A to 32D may be disposed such that the respective second widths W12A to W12D differ from each other. In the semiconductor device A16, the second trench parts 32A to 32D are disposed such that the second widths W12A to W12D become larger from the first substrate surface 211 toward the second substrate surface 212 of the semiconductor substrate 21.

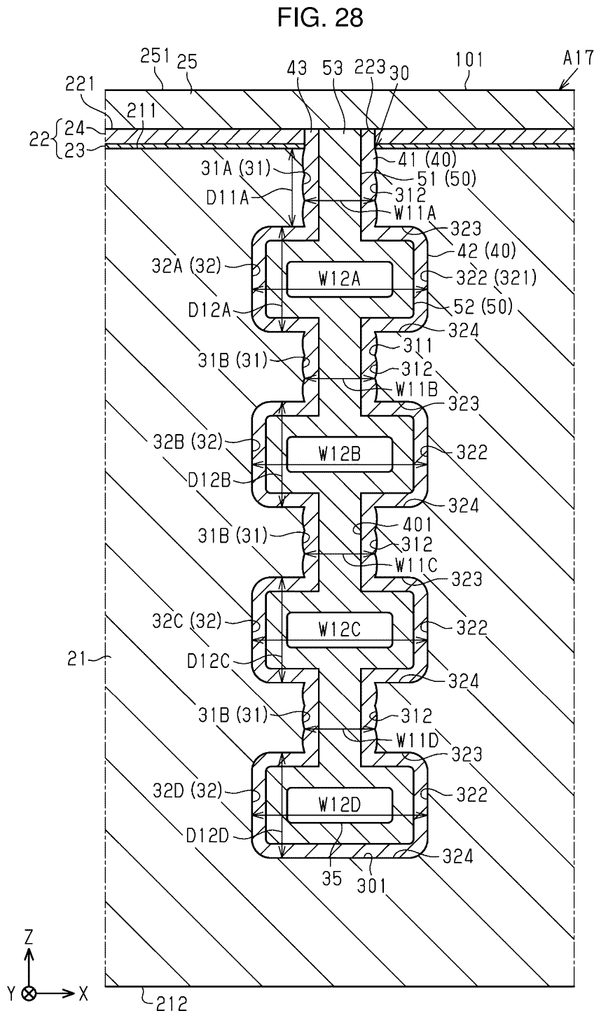

FIG. 28 is a schematic cross-sectional view showing a semiconductor device A17 of a modification example. In this semiconductor device A17, the first trench parts 31A to 31D include a plurality of recesses and protrusions 312 on the respective inner surfaces 311. The plurality of recesses and protrusions 312 are arranged from the first substrate surface 211 toward the second substrate surface 212 of the semiconductor substrate 21. The plurality of recesses and protrusions 312 extend along the XY plane. The plurality of recesses and protrusions 312 extend along the XY plane in a stripe shape. It can be said that the plurality of recesses and protrusions 312 extend along the circumference direction of the first trench part 31. The first trench parts 31A to 31D may be formed by deep-etching. The plurality of recesses and protrusions 312 may be formed by isotropic etching in the deep-etching method.

The first width W11A of the first trench parts 31A may change within the first trench part 31A along the z-axis direction. In one example, the first trench part 31A may be disposed such that the first width W11A gradually decreases from the first substrate surface 211 toward the second substrate surface 212 of the semiconductor substrate 21 in the z-axis direction. Also, the first trench part 31A may be disposed such that the first width W11A gradually increases from the first substrate surface 211 toward the second substrate surface 212 of the semiconductor substrate 21 in the z-axis direction. The first trench part 31A may be configured such that the first width W11A at the center in the z-axis direction is larger or smaller than the first width W11A at the top or bottom end of the first trench part 31A in the z-axis direction.

The first trench parts 31B to 31D may also be configured such that the first widths W11B to W11D differ from each other within the first trench parts 31B to 31D respectively in a manner similar to the first trench part 31A.

Some of the first trench parts 31A to 31D may have a different shape. For example, the first trench part 31A may be disposed such that the first width W11A gradually decreases from the first substrate surface 211 toward the second substrate surface 212, and the first trench part 31B may be disposed such that the first width W11B gradually increases from the first substrate surface 211 toward the second substrate surface 212. Also, the first trench part 31A may be disposed such that the first width W11A remains constant from the first substrate surface 211 toward the second substrate surface 212, and the first trench part 31B may be disposed such that the first width W11B gradually increases from the first substrate surface 211 toward the second substrate surface 212.

The term “on” used in the present disclosure encompasses both “on” and “above” unless otherwise clearly indicated by the context. Thus, “the first layer is formed on the second layer” is intended to mean “the first layer is formed directly on the second layer and touching the second layer” in some embodiments, and “the first layer is formed above the second layer, not touching the second layer” in other embodiments. That is, the term “on” does not exclude any structure in which another layer is formed between the first layer and the second layer.

The z-axis direction used in this disclosure does not necessarily have to be the vertical direction, and does not necessarily have to completely coincide with the vertical direction. Therefore, in the various structures according to the present disclosure (for example, the structure illustrated in FIG. 1), the “up” and “down” in the z-axis direction described in the present disclosure are not limited to “up” and “down” in the vertical direction. For example, the x-axis direction may be the vertical direction, or the y-axis direction may be the vertical direction.

### (Supplementary Notes)

The technical ideas that can be understood from this disclosure are described below. For the purpose of aiding understanding and not intending to be limiting, the components described in the supplementary notes are given the reference characters of the corresponding components in the embodiments. Reference characters are shown as examples to aid in understanding, and components described in each supplementary note should not be limited to the components indicated by the reference characters.

### (Supplementary Note 1)

A semiconductor device, including:
semiconductor substrate (21) having a first substrate surface (211) and a second substrate surface (212) on the opposite side to the first substrate surface (211);
a trench (30) recessed from the first substrate surface (211) toward the second substrate surface (212), and has a width when viewed from a thickness direction (Z) of the semiconductor substrate (21);
an insulating layer (40) disposed inside the trench (30); and
an electrode part (50) disposed inside the trench (30) and surrounded by the insulating layer (40), the electrode part having conductivity;
wherein the trench (30) includes:
a first trench part (31) having a first width (W11) in a width direction of the trench (30); and
a second trench part (32) disposed at a position differing from the first trench part (31) in the thickness direction (Z) and having a second width (W12) that is greater than the first width (W11) in the width direction.

### (Supplementary Note 2)

The semiconductor device according to Supplementary Note 1, wherein the trench (30) has a stepped surface between the first trench part (31) and the second trench part (32).

### (Supplementary Note 3)

The semiconductor element according to Supplementary Note 1 or 2, wherein a plurality of the first trench parts (31) and a plurality of the second trench parts (32) are disposed, and wherein the plurality of first trench parts (31) and the plurality of second trench parts (32) are alternately arranged along the thickness direction (Z).

### (Supplementary Note 4)

The semiconductor element according to Supplementary Note 3, wherein the first trench part (31) includes:
a surface trench part (31A) that opens at the first substrate surface (211); and
middle trench parts (31B to 31D) disposed between two of the second trench parts (32) arranged along the thickness direction (Z), and
wherein a length of the surface trench part (31A) in the thickness direction (Z) is equal to a length of the middle trench parts (31B to 31D).

### (Supplementary Note 5)

The semiconductor element according to Supplementary Note 4, wherein the first widths (W11B to W11D) of the middle trench parts (31B to 31D) are smaller than the first width (W11A) of the surface trench part.

### (Supplementary Note 6)

The semiconductor element according to Supplementary Note 4 or 5, wherein a length of the second trench part (32) in the thickness direction (Z) is greater than the length of the middle trench parts.

### (Supplementary Note 7)

The semiconductor device according to any one of Supplementary Notes 1 to 6, wherein an inner surface of the first trench part (31) includes a plurality of recesses and protrusions arranged from the first substrate surface (211) towards the second substrate surface (212), and
wherein the plurality of recesses and protrusions extend along a circumference direction of the first trench part (31).

### (Supplementary Note 8)

The semiconductor device according to any one of Supplementary Notes 1 to 7, wherein the second trench part (32) includes side surfaces (322) that face each other in the width direction, and
wherein, when viewed from the thickness direction (Z), respective distances between the inner surfaces of the first trench part (31) and the side surfaces (322) of the second trench part (32) are equal to a depth of the second trench part (32) in the thickness direction (Z).

### (Supplementary Note 9)

The semiconductor element according to Supplementary Note 8, wherein the plurality of second trench parts (32) are disposed such that distances (W11A to W11D) between the side surfaces (322) thereof differ from each other.

### (Supplementary Note 10)

The semiconductor element according to Supplementary Note 9, wherein the plurality of second trench parts (32) are disposed such that distances (W11A to W11D) between the side surfaces (322) thereof decrease gradually from the first substrate surface (211) toward the second substrate surface (212).

### (Supplementary Note 11)

The semiconductor element according to Supplementary Note 9, wherein the plurality of second trench parts (32) are disposed such that distances (W11A to W11D) between the side surfaces (322) thereof increase gradually from the first substrate surface (211) toward the second substrate surface (212).

### (Supplementary Note 12)

The semiconductor device according to any one of Supplementary Notes 1 to 11, wherein, when viewed from the thickness direction (Z), the trench (30) extends in a length direction that intersects with the width direction.

### (Supplementary Note 13)

The semiconductor device according to any one of Supplementary Notes 1 to 12, wherein a plurality of the trenches (30) are arranged separately from each other along the width direction (X), and
wherein a distance (L32) between two of the second trench parts (32) adjacent to each other along the width direction (X) is smaller than the second width (W12).

### (Supplementary Note 14)

The semiconductor device according to any one of Supplementary Notes 1 to 13, wherein, when viewed from the thickness direction (Z), the trenches (30) are arranged along a length direction that intersects with the width direction (X).

### (Supplementary Note 15)

The semiconductor device according to any one of Supplementary Notes 1 to 14, wherein the first trench part (31) includes a plurality of holes (73) extending in the thickness direction (Z) and arranged along the width direction (X), and
wherein the second trench part (32) extends in the width direction (X) to straddle the plurality of holes (73), and the second trench part (32) runs through the plurality of holes (73).

### (Supplementary Note 16)

The semiconductor element according to Supplementary Note 15, wherein the plurality of holes (73) include a first hole (731) and a second hole (732) disposed at respective ends in the width direction (X),
wherein the second trench part (32) includes a first side surface (721) and a second side surface (722) that face each other in the width direction (X),
wherein the first side surface (721) of the second trench part (32) is located on a side opposite to the second hole (732) with respect to the first hole (731), and
wherein the second side surface (722) of the second trench part (32) is located on a side opposite to the first hole (731) with respect to the second hole (732).

### (Supplementary Note 17)

The semiconductor element according to Supplementary Note 16, wherein a distance (L51) between the plurality of holes (73) is smaller than twice the distance (L52) between the first hole (731) and the first side surface (721).

### (Supplementary Note 18)

The semiconductor device according to any one of Supplementary Notes 1 to 17, including a hollow (35) formed in the second trench (32) and surrounded by the electrode part (50).

### (Supplementary Note 19)

The semiconductor device according to any one of Supplementary Notes 1 to 18, wherein a plurality of the trenches (30) are disposed, and
wherein, when viewed from the thickness direction (Z), the plurality of trenches include a first trench (30AA, 30AB) extending in a first direction and a second trench (30BA, 30BB) extending in a second direction that intersects with the first direction.

### (Supplementary Note 20)

The semiconductor device according to Supplementary Note 19, wherein the first trench (30AA, 30AB) and the second trench (30BA, 30BB) are connected with each other.

### (Supplementary Note 21)

The semiconductor element according to Supplementary Note 19, wherein the first trench and the second trench are separated from each other.

### (Supplementary Note 22)

A manufacturing method of a semiconductor device, including:
forming a first trench part (31) having a first width (W11) when viewed from a thickness direction (Z) of a semiconductor substrate (21) having a first substrate surface (211) and a second substrate surface (212) on a side opposite to the first substrate surface (211) by etching the semiconductor substrate (21),
forming a second trench part (32) having a second width (W12) that is greater than the first width (W11) of the first trench part (31) when viewed from the thickness direction (Z) by performing isotropic etching on the semiconductor substrate (21) through the first trench part (31),
forming an insulating layer (40) on inner surfaces of the first trench part (31) and the second trench part (32), and
forming an electrode part (50) that has conductivity in the first trench part (31) and the second trench part (32) such that the electrode part is surrounded by the corresponding insulating layer (40).

### (Supplementary Note 23)

The manufacturing method of a semiconductor device according to Supplementary Note 22, including:
a first etching step of forming the first trench part (31) by performing deep-etching on the semiconductor substrate (21), and
a second etching step of forming the second trench part (32) by performing isotropic etching on the semiconductor substrate (21).

### (Supplementary Note 24)

The manufacturing method of a semiconductor device according to Supplementary Note 23, wherein the trench including a plurality of first trench parts (31) and a plurality of second trench parts (32) is formed by repeating the first etching step and the second etching step in an alternate manner.

The descriptions above are merely illustrative. Those skilled in the art may recognize that many more possible combinations and permutations are possible other than the components and methods (manufacturing processes) enumerated for purposes of illustrating the technology of the present disclosure. The present disclosure is intended to embrace any alternatives, modifications, and variations that fall within the scope of the present disclosure, including the claims.

What is claimed is:

1. A semiconductor device, comprising:
a semiconductor substrate having a first substrate surface and a second substrate surface opposite to each other;
a trench recessed from the first substrate surface toward the second substrate surface, and has a width when viewed from a thickness direction of the semiconductor substrate;
an insulating layer disposed inside the trench; and
an electrode part disposed inside the trench and surrounded by the insulating layer, the electrode part having conductivity, wherein
the trench includes:
a first trench part having a first width in a width direction of the trench, and
a second trench part formed at a position different from that of the first trench part in the thickness direction and having a second width that is greater than the first width in the width direction.

2. The semiconductor device according to claim 1, wherein the trench has a stepped surface between the first trench part and the second trench part.

3. The semiconductor device according to claim 1, wherein
each of the first trench part and the second trench part is provided in a plurality, and
the plurality of first trench parts and the plurality of second trench parts are alternately arranged along the thickness direction.

4. The semiconductor device according to claim 3, wherein
the plurality of first trench parts includes:
a surface trench part that is formed at the first substrate surface; and
a middle trench part that is located between the surface trench part and the second substrate surface, the middle trench part being between two of the plurality of second trench parts in the thickness direction, and
wherein a length of the surface trench part in the thickness direction is equal to a length of the middle trench part.

5. The semiconductor device according to claim 4, wherein the middle trench part is narrower than the surface trench part in the width direction of the trench.

6. The semiconductor device according to claim 4, wherein the second trench part is longer than the middle trench part in the thickness direction.

7. The semiconductor device according to claim 1, wherein
an inner surface of the first trench part includes a plurality of recesses and protrusions arranged from the first substrate surface towards the second substrate surface, each of the plurality of recesses and protrusions extending along a circumferential direction around the first trench part.

8. The semiconductor device according to claim 1, wherein
the second trench part includes side surfaces that face each other in the width direction,
the first trench part has inner surfaces that correspond to the side surfaces of the second trench part, respectively, in the width direction, a distance between one of the side surfaces of the second trench part and one of the inner surfaces of the first trench part corresponding thereto being a first distance, and
the first distance is equal to a depth of the second trench part in the thickness direction.

9. The semiconductor device according to claim 8, wherein
the second trench part is provided in a plurality along the thickness direction, each second trench parts having a distance between the side surfaces thereof, which is a second distance, and
the plurality of second trench parts are disposed such that the plurality of second distances differ from one another.

10. The semiconductor device according to claim 9, wherein the plurality of second distances are of gradually-decreased values in the thickness direction from the first substrate surface toward the second substrate surface.

11. The semiconductor device according to claim 9, wherein the plurality of second distances are of gradually-increased values in the thickness direction from the first substrate surface toward the second substrate surface.

12. The semiconductor device according to claim 1, wherein the trench extends in a length direction that intersects with the width direction.

13. The semiconductor device according to claim 1, wherein
the trench is provided in a plurality,
the plurality of the trenches are arranged separately from one another along the width direction, and
a distance between two of the second trench parts adjacent to each other in the width direction is smaller than the second width.

14. The semiconductor device according to claim 13, wherein, each of the plurality trenches is arranged along a length direction that intersects with the width direction.

15. The semiconductor device according to claim 1, wherein
the first trench part includes a plurality of holes extending in the thickness direction and arranged along the width direction,
the second trench part extends in the width direction to straddle the plurality of holes, and
the second trench part runs through the plurality of holes.

16. The semiconductor device according to claim 15, wherein
the plurality of holes include a first hole and a second hole arranged in the width direction,
the second trench part includes a first side surface and a second side surface that face each other in the width direction,
the first side surface of the second trench part and the second hole are located on opposite sides of the first hole, and
the second side surface of the second trench part and the first hole are located on opposite sides of the second hole.

17. The semiconductor device according to claim 16, wherein in the width direction, a distance between adjacent two of the plurality of holes is smaller than twice a distance between the first hole and the first side surface.

18. The semiconductor device according to claim 1, wherein the second trench part has a hollow formed therein and surrounded by the electrode part.

19. The semiconductor device according to claim 1, wherein
the trench is provided in a plurality, and
when viewed from the thickness direction, the plurality of trenches include:
a first trench extending in a first direction, and
a second trench extending in a second direction that intersects with the first direction.

20. The semiconductor device according to claim 19, wherein the first trench and the second trench are connected with each other.
